(19) United States
(12) Patent Application Publication
(10) Pub. No.: US 2026/0038563 A1
(43) Pub. Date: Feb. 5, 2026

(54) APPARATUSES, SYSTEMS, AND METHODS TO REFRESH MULTIPLE MEMORY BANKS

(71) Applicant: Micron Technology, Inc., Boise, ID (US)

(72) Inventors: Wonjun Choi, Boise, ID (US); Hyun Yoo Lee, Boise, ID (US)

(73) Assignee: Micron Technology, Inc., Boise, ID (US)

(21) Appl. No.: 19/271,624

(22) Filed: Jul. 16, 2025

Related U.S. Application Data
(60) Provisional application No. 63/677,719, filed on Jul. 31, 2024.

(51) Int. Cl. G11C 11/406

(52) U.S. Cl. CPC G11C 11/40618

(57) ABSTRACT

Apparatuses and methods for a multi-bank refresh operation performed on a subset of memory banks from a plurality of memory bank of a memory device. The subset of memory banks may be determined by a seed address and a mask code. The seed address and the mask code may be part of the multi-bank refresh command, or the mask code may be stored in a mode register. A memory device may perform a mask operation using the seed address and the mask code to identify a set of memory banks on which a refresh operation will be performed and memory banks to be masked. The masked memory banks may not have a refresh operation performed on them, thus making them available for access operations during a refresh operation.

### CROSS-REFERENCE TO RELATED APPLICATIONS

This application claims the filing benefit of U.S. Provisional Application No. 63/677,719, filed Jul. 31, 2025. This application is incorporated by reference herein in its entirety and for all purposes.

### BACKGROUND

Information may be stored on memory cells of a memory device. The memory cells may be organized at the intersection of word lines, arranged as rows, and bit lines, arranged as columns. The memory cells may be further organized into memory banks. Information in the memory cells may decay over time. For example, the information may be stored as a charge on a capacitor which may decay over time. The memory device may perform refresh operations to restore the information and prevent information from being lost.

### BRIEF DESCRIPTION OF DRAWINGS

FIG. 1 illustrates a block diagram of an example system according to an embodiment of the disclosure.

FIG. 2 is a block diagram of a semiconductor device according to at least one embodiment of the disclosure.

FIG. 3 is a command table representing the commands for refresh operations according to some embodiments of the present disclosure.

FIG. 4a is a diagram of a memory array according to some embodiments of the present disclosure.

FIG. 4b is a diagram of a multi-bank refresh operation according to some embodiments of the present disclosure.

FIG. 4c is a diagram of a multi-bank refresh operation according to some embodiments of the present disclosure.

FIG. 4d is a diagram of a multi-bank refresh operation according to some embodiments of the present disclosure.

FIG. 4e is a diagram of a multi-bank refresh operation according to some embodiments of the present disclosure.

FIG. 4f is a diagram of a multi-bank refresh operation according to some embodiments of the present disclosure.

FIG. 4g is a diagram of a multi-bank refresh operation according to some embodiments of the present disclosure.

FIG. 4h is a diagram of a multi-bank refresh operation according to some embodiments of the present disclosure.

FIG. 5 is a command table representing the commands for refresh operations according to some embodiments of the present disclosure.

FIG. 6 is a diagram of multi-bank refresh operations with a preset mask code according to some embodiments of the present disclosure.

FIG. 7 is a diagram of multi-bank refresh operations with a preset mask code according to some embodiments of the present disclosure.

FIG. 8 is a table representing the relative timing of multi-bank refresh operations according to some embodiments of the present disclosure.

FIG. 9 is a flow chart of a method of performing a multi-bank refresh operation according to some embodiments of the present disclosure.

FIG. 10 is a flow chart of a method of performing a multi-bank refresh operation with a preset mask code according to some embodiments of the present disclosure.

FIG. 11 is a flow chart of a method of performing a multi-bank refresh operation according to some embodiments of the present disclosure.

FIG. 12 is a flow chart of a method of performing a multi-bank refresh operation according to some embodiments of the present disclosure.

### DETAILED DESCRIPTION

The following description of certain embodiments is merely exemplary in nature and is in no way intended to limit the scope of the disclosure or its applications or uses. In the following detailed description of embodiments of the present systems and methods, reference is made to the accompanying drawings which form a part hereof, and which are shown by way of illustration specific embodiments in which the described systems and methods may be practiced. These embodiments are described in sufficient detail to enable those skilled in the art to practice presently disclosed systems and methods, and it is to be understood that other embodiments may be utilized, and that structural and logical changes may be made without departing from the spirit and scope of the disclosure. Moreover, for the purpose of clarity, detailed descriptions of certain features will not be discussed when they would be apparent to those with skill in the art so as not to obscure the description of embodiments of the disclosure. The following detailed description is therefore not to be taken in a limiting sense, and the scope of the disclosure is defined only by the appended claims.

Memory devices store information in memory arrays. A memory array may include multiple memory banks. A memory bank may contain multiple word lines. Information in a memory array may be accessed by one or more access operations, such as read or write operations. During an example access operation, a word line may be activated based on a row address and then selected memory cells along that active word line may have their information read from or written to, based on which bit lines are accessed. The bit lines that are accessed may be based on a column address.

The memory array may be refreshed on a row-by-row basis, for example as part of a refresh operation, where the memory cells along each row are refreshed periodically. The frequency at which the rows are refreshed, or the maximum time any given row will go between refreshes, may be determined based on a refresh specification. During a refresh operation, the memory bank being refreshed is inaccessible for read or write operations. The number of refresh commands and the length of time a refresh operation lasts may depend on factors such as the type of refresh operation. For example, a refresh operation that is performed on all memory banks simultaneously will cause all memory banks of the array to be inaccessible for the duration of the refresh operation. Another refresh operation may be performed on only a subset of the memory banks at a time. During such a refresh operation, only the subset of banks will be inaccessible for the duration of the refresh operation and all other banks will be accessible. Additionally, because the subset of banks may be a smaller number of banks than the total number of memory banks, the amount of time the refresh operation performed on a subset of banks takes to complete may be less than the amount of time a refresh operation performed on all banks of the memory array takes. Thus, there may be a need to vary the amount of time a refresh operation takes to complete and/or the number of banks that are inaccessible during a refresh operation.

The present disclosure is drawn to apparatuses, systems, and methods for multi-bank refresh operations performed on memory banks in a memory device. During a multi-bank refresh operation, the memory banks on which the refresh operation is performed may be determined by a seed address and a mask code. For example, the refresh operation may be performed on a subset of the memory banks of the memory device. The memory device may perform a mask operation using the seed address and the mask code to identify a set of memory banks on which a refresh operation will be performed and a set of memory banks to be masked. The masked memory banks may not have a refresh operation performed on them, thus making them available for access operations during the refresh operation performed on the other memory banks. The amount of time it takes to complete a refresh operation may be determined by the number of memory banks having a refresh operation performed on them. For example, a multi-bank refresh operation with a mask code that identifies a small number of memory banks for the refresh operation may take less time to complete the refresh operation than a multi-bank refresh operation with a mask code that identifies a large number of memory banks for the refresh operation. In some embodiments, the mask code may be set by a user, thus the user may have some control in determining the amount of time a memory device takes to complete a refresh operation.

In an example implementation, a memory device includes a refresh control circuit. The memory device receives a multi-bank refresh command, and responsive to the multi-bank refresh command, the refresh control circuit receives a seed address and a mask code. The refresh control circuit may perform a mask operation based on the seed address and the mask code to identify a subset of the memory banks of the memory device. Based on the mask operation, the refresh control circuit will cause the identified subset of memory banks to have a refresh operation performed on them.

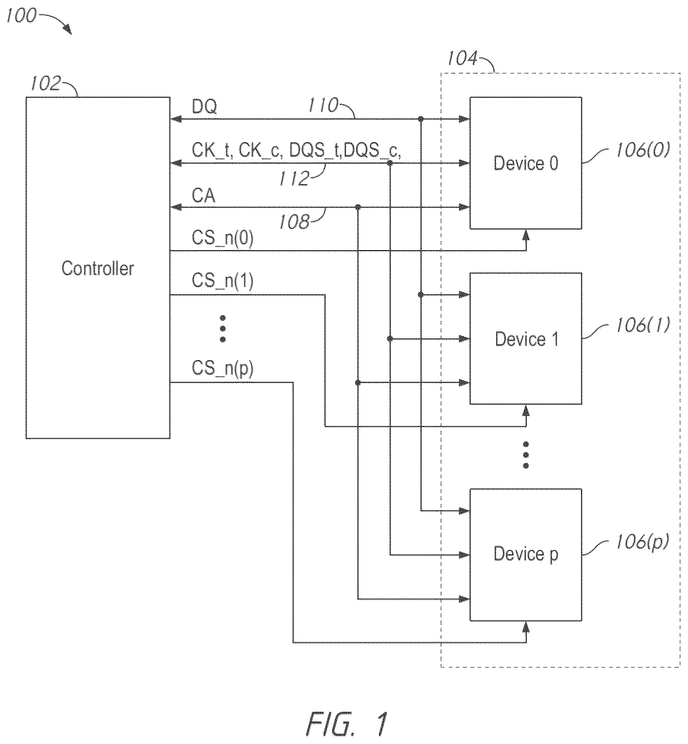

FIG. 1 illustrates a block diagram of an example system according to an embodiment of the disclosure. The system 100 includes a controller 102 and a memory system 104. In the illustrated embodiment, the memory system 104 includes memory devices 106(0)-106(p) (e.g., “Device 0” through “Device p”), where p is a number greater than one (1).

In one embodiment, the memory system 104 is a memory module and the memory devices 106(0)-106(p) are memory ranks. The memory devices 106(0)-106(p) may include a dynamic random-access memory (DRAM), a double data rate (DDR) memory, a low power double data rate (LPDDR) memory, a graphics double data rate (GDDR) memory, or other type of memory. Each memory rank can include one or more memory devices (e.g., DRAM devices).

The memory devices 106(0)-106(p) are each coupled to the command/address, data, and clock buses. The controller 102 and the memory system 104 are in communication over several buses. Commands and addresses (CA) are received by the memory system 104 on a command/address bus 108, and data (DQ) is provided between the controller 102 and the memory system 104 over a data bus 110. Various clocks may be provided between the controller 102 and the memory system 104 over a clock bus 112. The clock bus 112 may include signal lines for providing system clocks CK_t and CK_c received by the memory system 104 and data clocks (strobes) DQS_t and DQS_c received by the memory system 104 and/or provided to the controller 102. Each of the buses may include one or more signal lines on which signals are provided.

The CK_t and CK_c clocks provided by the controller 102 to the memory system 104 are used for timing the provision and receipt of the commands and addresses. The DQS_t and DQS_c clocks are used for timing provision of data. The CK_t and CK_c clocks are complementary, and the DQS_t and DQS_c clocks are complementary. Clocks are complementary when a rising edge of a first clock occurs at a same time as a falling edge of a second clock, and when a rising edge of the second clock occurs at a same time as a falling edge of the first clock.

The controller 102 provides commands to the memory system 104 to perform memory operations. Examples of memory commands include timing commands for controlling the timing of various operations, explicit power-down entry and exit commands and commands for auto power-down for controlling entry into power-down, access commands for accessing the memory, such as read commands for performing read operations and write commands for performing write operations, activation commands, refresh command, activate command, pre-charge command, deselect command, no operation commands, as well as other commands. The command signals provided by the controller 102 to the memory system 104 further include external control signals (e.g., chip select signals CS_n(0), CS_n(1), CS_n(p)).

The memory devices 106(0)-106(p) are provided the commands, addresses, data, and clocks, and the external control signals provided on respective select signal lines are used to select which of the memory devices 106(0)-106(p) (or memory ranks) will respond to the command and perform the corresponding operation. In some embodiments, a respective control signal is provided to each memory device 106(0)-106(p) of the memory system 104. In some embodiments, the memory devices included in a rank are provided a same control signal. The controller 102 provides an active control signal to select the corresponding memory device 106(0)-106(p). While the respective control signal is active, the corresponding memory device 106(0)-106(p) is selected to receive the commands and addresses provided on the command/address bus 108. In some embodiments, the external control signal is used in combination with the CA signals to indicate different memory commands and memory operations.

In operation, when an activate and a read command, and associated address are provided by the controller 102 to the memory system 104, the memory device 106(0)-106(p) selected by the external control signals receives the activate and read commands and associated address and performs a read operation to provide the controller 102 with read data from a memory location corresponding to the associated address. The read data is provided by the selected memory device 106(0)-106(p) to the controller 102 according to a timing relative to receipt of the read command. For example, the timing may be based on a read latency (RL) value that indicates the number of clock cycles of the CK_t and CK_c clocks (a clock cycle of the CK_t and CK_c clocks is referenced as tCK) after the read command when the read data is provided by the selected memory device 106(0)-106(p) to the controller 102.

The RL value is programmed by the controller 102 in the memory devices 106(0)-106(p). For example, the RL value may be programmed in respective mode registers of the memory devices 106(0)-106(p). As known, mode registers included in each of the memory devices 106(0)-106(p) may be programmed with information for setting various operating modes and/or to select features for operation of the memory devices 106(0)-106(p). One of the settings may be for the RL value. In some embodiments of the disclosure, mode register settings may include refresh configurations, such as related to a multi-bank refresh operation according to some embodiments of the disclosure.

In preparation of the selected memory device 106(0)-106(p) providing the read data to the controller 102, the memory device provides active data clocks DQS_t and DQS_c. A clock is active when the clock transitions between low and high clock levels periodically. Conversely, a clock is inactive when the clock maintains a constant clock level and does not transition periodically. The DQS_t and DQS_c clocks are provided by the memory device 106(0)-106(p) performing the read operation to the controller 102 for timing the provision of read data to the controller 102. The controller 102 may use the DQS_t and DQS_c clocks for receiving the read data.

In operation, when an activate command and a write command, and associated address are provided by the controller 102 to the memory system 104, the memory device 106(0)-106(p) selected by the external control signals receives the activate and write commands and associated address and performs a write operation to write data from the controller 102 to a memory location corresponding to the associated address. The write data is provided to the selected memory device 106(0)-106(p) by the controller 102 according to a timing relative to receipt of the write command. For example, the timing may be based on a write latency (WL) value that indicates the number of clock cycles of the CK_t and CK_c clocks after the write command when the write data is provided to the selected memory device 106(0)-106(p) by the controller 102. The WL value is programmed by the controller 102 in the memory devices 106(0)-106(p). For example, the WL value may be programmed in respective mode registers of the memory devices 106(0)-106(p).

In preparation of the selected memory device 106(0)-106(p) receiving the write data from the controller 102, the controller 102 provides active data clocks DQS_t and DQS_c to the memory system 104. The DQS_t and DQS_c clocks may be used by the selected memory device 106(0)-106(p) to generate internal clocks for timing the operation of circuits to receive the write data. The data is provided by the controller 102 and the selected memory device 106(0)-106(p) receives the write data according to the DQS_t and DQS_c clocks, which is written to a memory location corresponding to the memory address.

One or more of the memory devices 106(0)-106(p) may include a multi-bank refresh feature according to embodiments of the disclosure. For example, in some embodiments of the disclosure, one or more of the memory devices 106(0)-106(p) may receive a multi-bank refresh command. In some embodiments, the multi-bank refresh command may be transmitted by the controller 102 on the command/address bus CA. In some embodiments, the multi-bank refresh command may include a seed address and a mask code. Based on the seed address and the mask code, the one or more memory devices 106(0)-106(p) may perform a mask operation to identify memory banks to refresh. In some embodiments, the multi-bank refresh command may contain the seed address and the mask code may be a setting in the mode register.

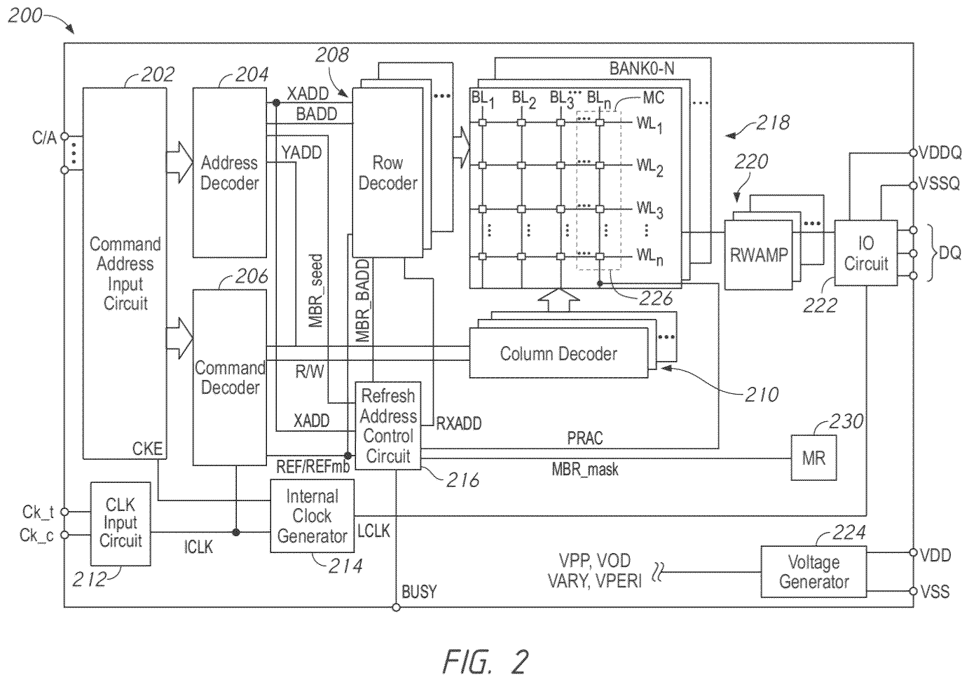

Mode register write commands and mode register read commands can be used to access the mode registers (e.g., mode register 230 in FIG. 2). In operation, when a mode register read command and associated address are provided by the controller 102 to the memory system 104, the memory device selected by the select signals receives the mode register read command and associated address and performs a mode register read operation to provide the controller 102 with information from the mode register corresponding to the associated address. The information from the selected mode register is provided to the controller 102. When a mode register write command and associated address are provided by the controller 102 to the memory system 104, the memory device selected by the select signals receives the mode register write command and associated address and performs a mode register write operation to write information provided by the controller 102 to a mode register corresponding to the associated address. The information is provided to the selected mode register by the controller 102.

FIG. 2 is a block diagram of a semiconductor device according to at least one embodiment of the disclosure. The semiconductor device 200 may be a semiconductor memory device, such as a DRAM device integrated on a single semiconductor chip. In some embodiments, the semiconductor device 200 may be an implementation of the one or more memory devices 106(0)-106(p) of FIG. 1.

The semiconductor device 200 includes a memory array 218. The memory array 218 is shown as including a plurality of memory banks. In the embodiment of FIG. 2, the memory array 218 is shown as including a number of memory banks BANK0-BANKN. For example, the memory may include 4 banks, 8 banks, 16 banks, or 128 banks. More or fewer banks may be included in the memory array 218 of other embodiments. The memory banks may be further organized into memory bank groups (not shown). For example, a device with thirty-two memory banks may be further organized into eight memory bank groups, with each bank group including four memory banks. Each memory bank includes a plurality of word lines WL arranged as rows, a plurality of bit lines BL arranged as columns, and a plurality of memory cells MC arranged at intersections of the plurality of word lines WL and the plurality of bit lines BL.

The selection of the word line WL is performed by a row decoder 208 and the selection of the bit lines BL is performed by a column decoder 210. In the embodiment of FIG. 2, the row decoder 208 includes a respective row decoder for each memory bank and the column decoder 210 includes a respective column decoder for each memory bank. The bit lines BL are coupled to a respective sense amplifier. Read data from the bit line BL is amplified by the sense amplifier and transferred to read/write amplifiers 220 over complementary local data lines, transfer gate, and complementary main data lines. Conversely, write data outputted from the read/write amplifiers 220 is transferred to the sense amplifier over the complementary main data lines, the transfer gate, and the complementary local data lines, and written in the memory cell MC coupled to the bit line BL.

Some of the memory cells may be set aside as counter memory cells 226. The counter memory cells may store per-row access count (PRAC) values PRAC, each of which is associated with one of the word lines. Each count value PRAC may be stored in counter memory cells 226 along the word line that the count value is associated with. The count value PRAC may be stored as a binary number, with each bit stored in a memory cell along the word line. For the sake of clarity, a single bit line of counter memory cells 126 is shown in FIG. 2. The number of counter memory cells along each word line may be based on a number of bits of the count value PRAC. In some embodiments, extra counter memory cells may be used. For example, more bits than the length of the number PRAC may be used to store error correction information for the count value PRAC.

The counter memory cells 226 may be referred to as such due to their use for storing the count values and may be structurally similar to, or identical to, the other memory cells of the array. The counter memory cells 226 may be grouped together at the end of the word line. Other distributions of the counter memory cells 226 along the word line may be used or the counter memory cells 226 may be otherwise associated with the word line. The counter memory cells 226 may not be directly accessible by external devices such as controllers (e.g., 102 of FIG. 1), for example to prevent the count values from being overwritten. In other words, the bit lines associated with the counter memory cells 226 may not be accessed by a normal column address.

The semiconductor device 200 may employ a plurality of external terminals that include command and address (C/A) terminals coupled to a command and address bus to receive commands and addresses, and a CS signal, clock terminals to receive clocks CK and/CK, data terminals DQ to provide data, and power supply terminals to receive power supply potentials VDD, VSS, VDDQ, and VSSQ.

The clock terminals are supplied with external clocks CK and/CK that are provided to an input circuit 212. The external clocks may be complementary. The input circuit 212 generates an internal clock ICLK based on the CK and/CK clocks. The ICLK clock is provided to the command decoder 210 and to an internal clock generator 214. The internal clock generator 214 provides various internal clocks LCLK based on the ICLK clock. The LCLK clocks may be used for timing operation of various internal circuits. The internal data clocks LCLK are provided to the input/output circuit 222 to time operation of circuits included in the input/output circuit 222, for example, to data receivers to time the receipt of write data.

The C/A terminals may be supplied with memory addresses. The memory addresses supplied to the C/A terminals are transferred, via a command/address input circuit 202, to an address decoder 204. The address decoder 204 receives the address and supplies a decoded row address XADD to the row decoder 208 and supplies a decoded column address YADD to the column decoder 210. The address decoder 204 may also supply a decoded bank address BADD, which may indicate the bank of the memory array 218 containing the decoded row address XADD and column address YADD. According to some embodiments, the address decoder 204 may also supply a decoded seed address MBR_seed to a refresh control circuit 216, which may indicate the bank of the memory array 218 to use for a mask operation for a multi-bank refresh operation. The C/A terminals may be supplied with commands. Examples of commands include timing commands for controlling the timing of various operations, access commands for accessing the memory, such as read commands for performing read operations and write commands for performing write operations, refresh commands to refresh memory in all banks of the memory array 218 and/or to refresh memory in a subset of banks of the memory array 218, as well as other commands and operations. The access commands may be associated with one or more row address XADD, column address YADD, and bank address BADD to indicate the memory cell(s) to be accessed.

The commands may be provided as internal command signals to a command decoder 206 via the command/address input circuit 202. The command decoder 206 includes circuits to decode the internal command signals to generate various internal signals and commands for performing operations. For example, the command decoder 206 may provide a row command signal to select a word line and a column command signal to select a bit line.

The device 200 may receive an access command which is a row activation command ACT. When the row activation command ACT is received, a bank address BADD and a row address XADD are timely supplied with the row activation command ACT.

The device 200 may receive an access command which is a read command. When a read command is received, a bank address BADD and a column address YADD are timely supplied with the read command, read data is read from memory cells in the memory array 218 corresponding to the row address XADD and column address YADD. The read command is received by the command decoder 206, which provides internal commands so that read data from the memory array 218 is provided to the read/write amplifiers 220. The read data is output to outside from the data terminals DQ via the input/output circuit 222. The access count PRAC stored in the counter memory cells 226 of the row associated with the row address XADD are read to the refresh address control circuit 216 and an updated value of the access count PRAC is written back to the counter memory cells 226 of the row XADD.

The device 200 may receive an access command which is a write command. When the write command is received, a bank address BADD and a column address YADD are timely supplied with the write command, write data supplied to the data terminals DQ is written to a memory cell MC in the memory array 218 corresponding to the row address and column address. The write command is received by the command decoder 206, which provides internal commands so that the write data is received by data receivers in the input/output circuit 222. Write clocks may also be provided to the external clock terminals for timing the receipt of the write data by the data receivers of the input/output circuit 222. The write data is supplied via the input/output circuit 222 to the read/write amplifiers 220 and by the read/write amplifiers 220 to the memory array 218 to be written into the memory cell MC. Similar to the read operation described above, the access count PRAC stored in counter memory cells 226 of the row associated with the row address XADD are read to the refresh address control circuit 216 and an updated value of the access count PRAC is written back to the counter memory cells 226 of the row XADD.

The semiconductor device 200 may also receive commands causing it to carry out refresh operations. For example, a controller of the memory may put the semiconductor device 200 into a refresh mode and provide a refresh command. Responsive to the refresh command, the command decoder 206 provides a refresh signal REF. The semiconductor device 200 may also enter a self-refresh mode where the refresh signal REF is repeatedly generated internally without additional refresh commands.

Responsive to the refresh signal REF, the refresh control circuit 216 performs one or more refresh operations by providing a refresh address RXADD, along with refresh signals (not shown) to the row decoder 208. The row decoder 208 refreshes the word line(s) associated with the refresh address RXADD, for example by restoring a charge in the memory cells along the word line(s) to an initial value associated with the value of the bit stored in that memory cell.

When the refresh control circuit 216 performs refresh operations responsive to REF, it determines if the refresh operations are normal refresh operations, targeted refresh operations, or combinations thereof. In a normal refresh operation, the refresh address RXADD is generated based on a sequence of addresses. In other words, the refresh address RXADD may be generated based on a previous value of the refresh address. For example, RXADD(i)=RXADD(i−1)+1. The sequence logic used to generate the normal refresh addresses may cycle through each of the word lines of the memory array 218. For instance, the refresh control circuit 216 may include an address counter and an address mapping circuit. The address counter may count through a sequence of values and the address mapping circuit may generate the refresh address RXADD based on the position of the count in the sequence.

The refresh control circuit 216 may selectively refresh a row from all of the memory banks or from a subset of the memory banks responsive to the refresh signal REF. For example, during a same bank refresh the refresh control circuit 216 may refresh a row from the same bank in each bank group. The refresh control circuit 216 may selectively refresh a row from a specific set of the memory banks, for example, responsive to the mode register setting. The mode register setting may be programmed in the mode register 230, for example, by a mode register write operation.

In a targeted refresh operation, the refresh address RXADD is generated based on an identified aggressor address stored in a targeted refresh queue of the refresh control circuit 216. The refresh address RXADD may represent victim addresses, which may be associated with word lines that have a spatial relationship with the word line associated with the identified aggressor address. For example, the refresh address RXADD may be word lines adjacent to the aggressor word line (e.g., RXADD=Aggressor+/−1). Other relationships (e.g., +/−2, +/−3, +/−4, etc.) may also be used.

The semiconductor device 200 may also receive commands causing it to carry out multi-bank refresh operations. For example, a controller of the memory may provide a multi-bank refresh command. Responsive to the multi-bank refresh command, the command decoder 206 provides a multi-bank refresh signal REFmb. In some embodiments, the multi-bank refresh signal may include a mask code. The mask code may be a sequence of digits, such as binary digits. The number of digits in the mask code may be determined by the number of memory banks 218 in the semiconductor device 200. For example, if the semiconductor device 200 includes 128 memory banks 218, the mask code may have eight digits.

Responsive to the multi-bank refresh command REFmb and the seed address MBR_seed, the refresh control circuit 216 may perform a mask operation to determine the set of memory bank addresses MBR_BADD on which to perform a refresh operation. The refresh control circuit 216 supplies a refresh row address RXADD and the set of memory bank addresses MBR_BADD to the row decoder 208, which refreshes a word line WL identified by the refresh row address RXADD in each of the memory banks in the subset of memory banks identified by the mask operation. In some embodiments, the mask code MBR_mask may be stored in a mode register 230 and responsive to the multi-bank refresh command REFmb from the command decoder 206, the refresh control circuit 216 may receive the mask code MBR_mask from the mode register 230 to perform the mask operation. The mask code MBR_mask may be programmed in the mode register 230, for example, by a mode register write operation. The refresh control circuit 216 may receive the mask code MBR_mask.

The memory device 200 includes one or more registers where information and/or settings of the device 200 are stored. For example, FIG. 2 shows a mode register 230, which includes a number of registers which may be used to store settings, properties, measured quantities, etc. related to the operation of the memory 200. For example, in some embodiments, the mode register 230 may store a mask code for mask operations during a multi-bank refresh operation.

The power supply terminals are supplied with power supply potentials VDD and VSS. The power supply potentials VDD and VSS are supplied to an internal voltage generator circuit 224. The internal voltage generator circuit 224 generates various internal potentials VPP, VARY, VPERI, and the like based on the power supply potentials VDD and VSS supplied to the power supply terminals. The internal potential VPP is mainly used in the row decoder 208, the internal potentials VARY are mainly used in the sense amplifiers included in the memory array 218 and the internal potential VPERI is used in many peripheral circuit blocks.

The power supply terminals are also supplied with power supply potentials VDDQ and VSSQ. The power supply potentials VDDQ and VSSQ are supplied to the input/output circuit 222. The power supply potentials VDDQ and VSSQ supplied to the power supply terminals may be the same potentials as the power supply potentials VDD and VSS supplied to the power supply terminals in an embodiment of the disclosure. The power supply potentials VDDQ and VSSQ supplied to the power supply terminals may be different potentials from the power supply potentials VDD and VSS supplied to the power supply terminals in another embodiment of the disclosure. The power supply potentials VDDQ and VSSQ supplied to the power supply terminals are used for the input/output circuit 222 so that power supply noise generated by the input/output circuit 222 does not propagate to the other circuit blocks.

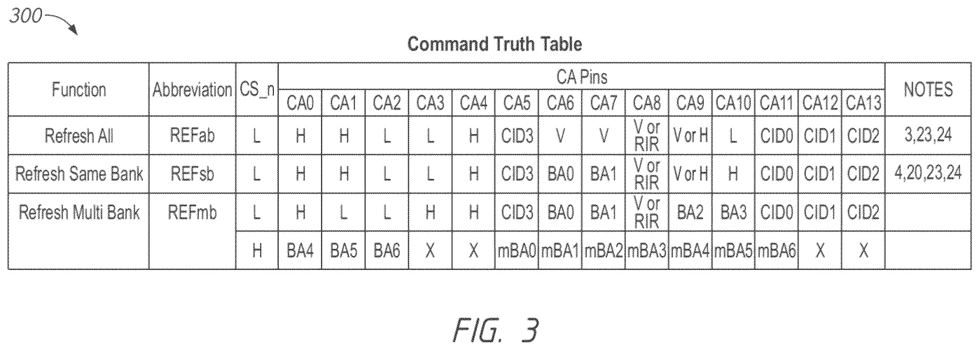

FIG. 3 is a command table representing the commands for refresh operations according to some embodiments of the present disclosure. For example, table 300 may represent external commands issued to a semiconductor device, such as semiconductor device 200, to perform refresh operations.

In some embodiments, each command represented by table 300 may represent a different refresh operation (e.g., REFab, REFsb, REFmb). For example, responsive to a REFab command, an all bank refresh operation is performed; responsive to a REFsb command, a same bank refresh operation is performed; and responsive to a REFmb command, a multi-bank refresh operation is performed.

In the table 300 of FIG. 3, “L” indicates a low logic state and “H” indicates a high logic state for the corresponding command terminal CA, “CIDn” indicates an nth bit of chip identification information, “BAm” indicates an mth bit of a bank address, “mBAp” indicates the pth bit of a mask code, “V” indicates a valid logic state, and “RIR” indicates a refresh interval rate.

In some embodiments, the commands represented by table 300 may be transmitted by a controller (e.g., 102 of FIG. 1). The command may be read by command/address input circuit (e.g., 202 of FIG. 2) and the command/address input circuit (e.g., 202 of FIG. 2) may transfer the bank address (e.g., BAm bits) to the address decoder (e.g., 204 of FIG. 2) and the command signals and the mask code (e.g., mBAp bits) to the command decoder (e.g., 206 of FIG. 2). The address decoder (e.g., 204 of FIG. 2) may supply a decoded seed address (e.g., MBR_seed) to a refresh control circuit (e.g., 216 of FIG. 2) based on the bank address (e.g., BAm bits), which may indicate the bank of the memory array (e.g., 218 of FIG. 2) to use for a multi-bank refresh operation. The command decoder (e.g., 206 of FIG. 2) may supply a decoded multi-bank refresh command (e.g., MBR) to the refresh control circuit (e.g., 216 of FIG. 2). The multi-bank refresh command (e.g., REFmb) may include the mask code (e.g., MBR_mask) based on the mask code bits (e.g., mBAp bits).

Responsive to the multi-bank refresh command (e.g., REFmb), the refresh control circuit (e.g., 216 of FIG. 2) may perform a multi-bank refresh operation on a subset of memory banks from the memory array (e.g., 218 of FIG. 2). The subset of memory banks may be identified by the refresh control circuit (e.g., 216 of FIG. 2) based on the seed address (e.g., MBR_seed) and the mask code. In some embodiments, the mask code is included in the multi-bank refresh command. In some embodiments, the mask code is programmed in a mode register (e.g., MBR_mask). In some embodiments, the refresh control circuit (e.g., 216 of FIG. 2) may perform a mask operation to identify the subset of memory banks. For example, the mask code may include a number, or a sequence, of binary digits and the mask operation may include applying the binary digits to the seed address (e.g., MBR_seed) such that a subset of memory banks is identified to have a refresh operation performed on it and the remaining memory banks are masked. The refresh control circuit (e.g., 216 of FIG. 2) will not perform a refresh operation on the masked memory banks.

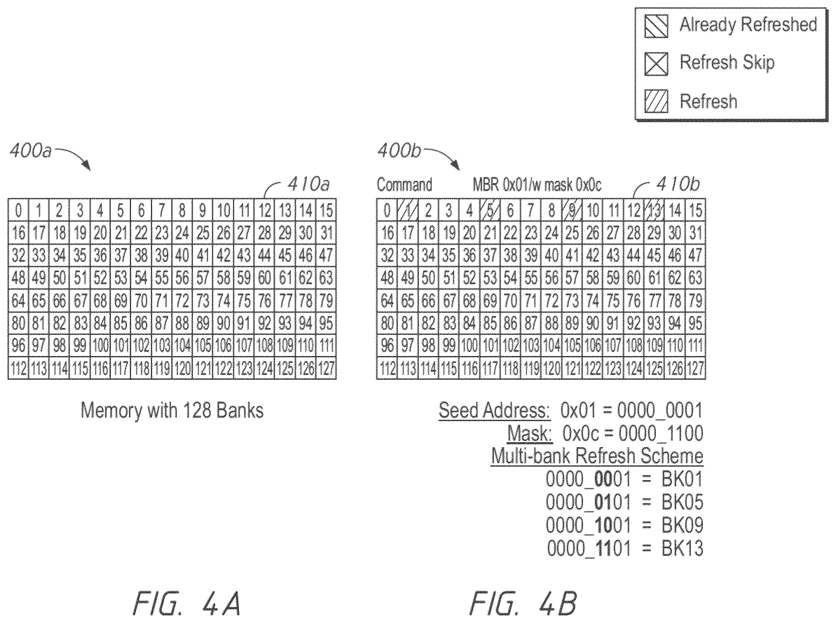

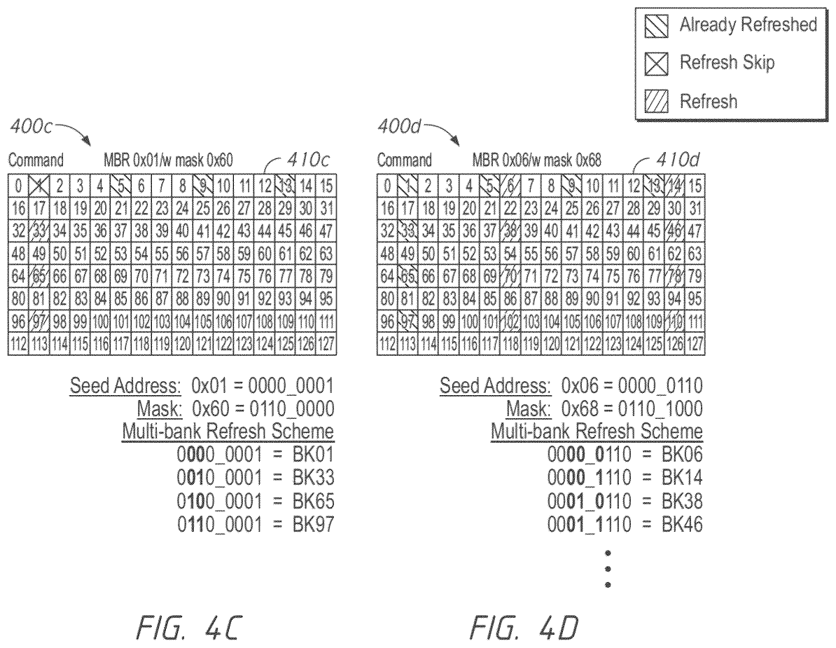

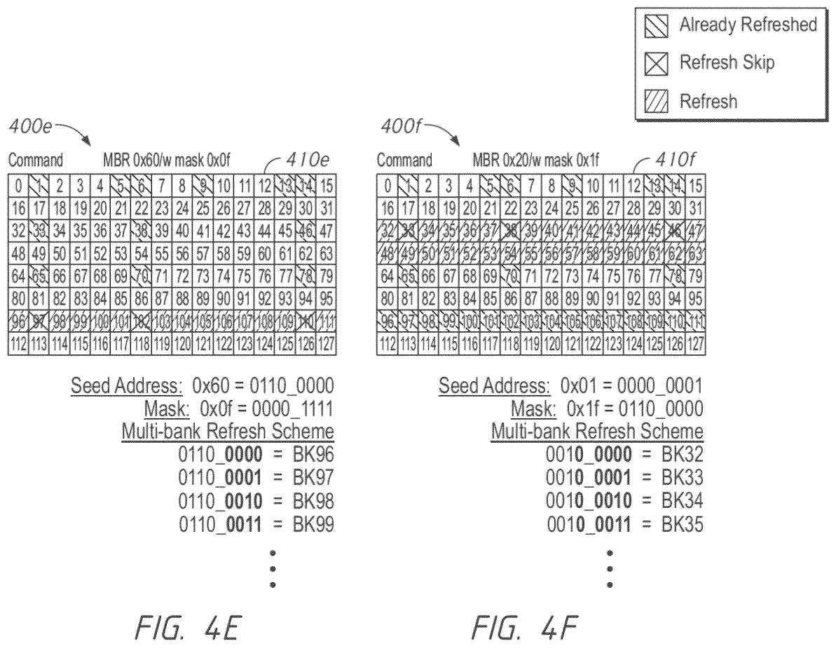

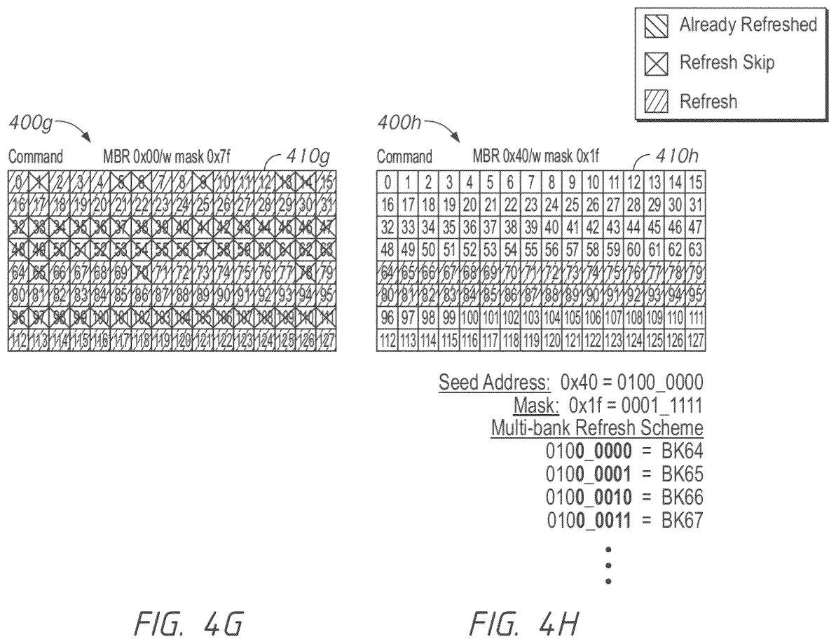

FIG. 4a is a diagram of a memory array according to some embodiments of the present disclosure. In some embodiments, memory array 400a may be an implementation of memory array 218 of FIG. 2. For example, the memory banks of FIG. 4a may be an implementation of the memory banks BANK0-BANKN of FIG. 2. The memory array 400a is shown with 128 memory banks. More or fewer banks may be included in the memory arrays of other embodiments.

FIG. 4b is a diagram of a multi-bank refresh operation according to some embodiments of the present disclosure. Memory array 410b may be an implementation of memory array 400a of FIG. 4a and/or memory array 218 of FIG. 2. For example, the memory banks of FIG. 4b may be an implementation of the memory banks BANK0-BANKN of FIG. 2. The memory array 410b is shown with 128 memory banks. More or fewer banks may be included in the memory arrays of other embodiments.

In some embodiments, the multi-bank refresh operation 400b may be an implementation of a multi-bank refresh operation performed responsive to the multi-bank refresh command REFmb of FIG. 3. During multi-bank refresh operation 400b, a row, such as a row associated with a row address RXADD of FIG. 2, may be refreshed in a subset of memory banks at one time. The subset of memory banks may be identified by a mask operation performed using a seed address (e.g., MBR_seed) and a mask code, which, in some embodiments, may be included in a multi-bank refresh command (e.g., REFmb). The seed address (e.g., MBR_seed) may be a bank address. The bank address may be identified as a binary number and/or a hexadecimal number. For example, in the embodiment of FIG. 4b, the seed address is 0000_0001 which translates to hexadecimal number 0x01. Binary bank address 0000_0001 may correspond to bank 1 of the memory array 410b (e.g., 400a of FIG. 4a and/or 218 of FIG. 2). The mask code may be represented as a series of binary digits, or bits, which may also be represented as a hexadecimal number. For example, in the embodiment of FIG. 4b, the mask code is 0000_1100 which can be represented as hexadecimal number 0x0c.

In an example mask operation, the subset of memory banks may be identified by applying the mask code to the seed address. For example, each binary digit of the series of binary digits that make up the mask code may be added individually and in combination to the binary digits of the seed address. The resulting series of binary digits of each combination then corresponds to a bank address to be included in the subset of memory banks to have a refresh operation performed on it during the multi-bank refresh operation. In the embodiment of FIG. 4b, the mask operation is performed with seed address 0000_0001 and mask code 0000_1100. The mask operation identifies a first bank of the subset of memory banks by changing the high bits, or “1”s, of the mask code to low, or “0” (e.g., 0000_0000) and applying the mask code to the seed address to identify bank address 0000_0001 as the first bank address of the subset of memory banks. This bank address identifies, when converted from a binary number to a decimal number, bank 1 as indicated in FIG. 4b by bank 1 being shaded.

The mask operation identifies a second bank of the subset of memory banks by changing one of the high bits, or “1”s, of the mask code to low, or “0” to create mask code 0000_0100 and applying the mask code to the seed address to identify bank address 0000_0101 as the second bank address of the subset of memory banks. This bank address, when converted from a binary number to a decimal number, identifies bank 5 as indicated in FIG. 4b by bank 5 being shaded.

The mask operation identifies a third bank of the subset of memory banks by changing a different one of the high bits, or “1”s, of the mask code to low, or “0” to create mask code 0000_1000 and applying the mask code to the seed address to identify bank address 0000_1001 as the third bank address of the subset of memory banks. This bank address, when converted from a binary number to a decimal number, identifies bank 9 as indicated in FIG. 4b by bank 9 being shaded.

Finally, the mask operation identifies a fourth bank of the subset of memory banks by applying the mask code without changes (e.g., 0000_1100) to the seed address to identify bank address 0000_1101 as the fourth bank address of the subset of memory banks. This bank address identifies bank 13 as indicated in FIG. 4b by bank 13 being shaded. Thus, the shaded banks 1, 5, 9, and 13 receive a refresh operation during the multi-bank refresh operation and the unshaded banks in FIG. 4b are masked during the multi-bank refresh operation. In other words, the unshaded banks do not receive a refresh operation during the multi-bank refresh operation.

In some embodiments, the number of high bits, or “1”s, included in the mask code may determine the number of banks to have a refresh operation performed at a time. For example, in the embodiment of FIG. 4b, the mask code includes two high bits resulting in four banks being included in the multi-bank refresh operation. Other mask codes may include more or fewer high bits and thus more or fewer banks may be included in the multi-bank refresh operation.

FIG. 4c is a diagram of a multi-bank refresh operation according to some embodiments of the present disclosure. Memory array 410c may be an implementation of memory array 400a of FIG. 4a and/or memory array 218 of FIG. 2. For example, the memory banks of FIG. 4c may be an implementation of the memory banks BANK0-BANKN of FIG. 2. The memory array 410c is shown with 128 memory banks. More or fewer banks may be included in the memory arrays of other embodiments.

In some embodiments, the multi-bank refresh operation 400c may be an implementation of a second multi-bank refresh operation performed responsive to a second multi-bank refresh command REFmb of FIG. 3 in a refresh period. During the second multi-bank refresh operation 400c, a row, such as a row associated with a row address RXADD of FIG. 2, may be refreshed in a second subset of memory banks at one time. The second subset of memory banks may be identified by a mask operation performed using the seed address (e.g., MBR_seed) and a second mask code, which may be included in a multi-bank refresh command (e.g., REFmb). The seed address (e.g., MBR_seed) may be a bank address. The bank address may be identified as a binary number and/or a hexadecimal number. For example, in the embodiment of FIG. 4c, the seed address is 0000_0001 which translates to hexadecimal number 0x01 and is the same seed address as was used in the first multi-bank refresh operation (e.g., 400b of FIG. 4b). In some embodiments, the seed address may change based on the second multi-bank refresh command. Binary bank address 0000_0001 may correspond to bank 1 of the memory array 410c (e.g., 400a of FIG. 4a, 410b of FIG. 4b, and/or 218 of FIG. 2). The second mask code may be represented as a series of binary digits, or bits, which may also be represented as a hexadecimal number. For example, in the embodiment of FIG. 4c, the mask code is 0110_0000 which can be represented as hexadecimal number 0x60.

In an example second mask operation, the second subset of memory banks may be identified by applying the second mask code to the seed address. For example, each binary digit of the series of binary digits that make up the mask code may be added individually and in combination to the binary digits of the seed address. The resulting series of binary digits of each combination then corresponds to a bank address to be included in the second subset of memory banks to have a refresh operation performed on it during the second multi-bank refresh operation. In the embodiment of FIG. 4c, the second mask operation is performed with seed address 0000_0001 and mask code 0110_0000. The mask operation identifies a first bank of the second subset of memory banks by changing the high bits, or “1”s, of the mask code to low, or “0” (e.g., 0000_0000) and applying the mask code to the seed address to identify bank address 0000_0001 as the first bank address of the subset of memory banks, or bank 1 when converted from a binary number to a decimal number as indicated in FIG. 4c.

If the bank associated with an identified bank address was identified as part of a subset of memory banks to have a multi-bank operation performed in an earlier multi-bank refresh operation during a same refresh period, then the bank will be skipped during the current multi-bank refresh operation. A refresh period may be the amount of time to complete refresh operations for an entire memory array 410c (e.g., 218 of FIG. 2, 400a of FIG. 4a, and/or 410b of FIG. 4b). For example, during a refresh period, a controller (e.g., 102 of FIG. 1) may issue multiple refresh commands. The refresh commands may be multi-bank refresh commands. If a multi-bank refresh command is issued and the mask operation associated with the multi-bank refresh command identifies a memory bank that was part of a subset of memory banks associated with an earlier multi-bank refresh operation within the same refresh period, the memory bank will be skipped during the current multi-bank refresh operation. In other words, the bank that had a prior refresh operation performed on it, will not have another refresh operation performed on it during the same refresh period. In the embodiment of FIG. 4c, the identified bank address, when converted from a binary number to a decimal number, identifies bank 1 as skipped because bank 1 was part of the subset of memory banks identified during the multi-bank refresh operation 400b of FIG. 4b as indicated in FIG. 4c by bank 1 being marked with an “X.”

The mask operation identifies a second bank of the second subset of memory banks by changing one of the high bits, or “1”s, of the mask code to low, or “0” to arrive at mask code 0010_0000 to create mask code 0010_0000 and applying the second mask code to the seed address to identify bank address 0010_0001 as the second bank address of the subset of memory banks. This bank address, when converted from a binary number to a decimal number, identifies bank 33 as indicated in FIG. 4c by bank 33 being shaded.

The mask operation identifies a third bank of the second subset of memory banks by changing a different one of the high bits, or “1”s, of the mask code to low, or “0” to create mask code 0100_0000 and applying the mask code to the seed address to identify bank address 0100_0001 as the third bank address of the subset of memory banks. This bank address identifies, when converted from a binary number to a decimal number, bank 65 as indicated in FIG. 4c by bank 65 being shaded.

Finally, the mask operation identifies a fourth bank of the second subset of memory banks by applying the mask code without changes to the seed address (e.g., 0110_0000) to identify bank address 0110_0001 as the fourth bank address of the second subset of memory banks. This bank address, when converted from a binary number to a decimal number, identifies bank 97 as indicated in FIG. 4c by bank 97 being shaded. Thus, the shaded banks 1, 33, 65, and 97, with bank 1 skipped, receive a refresh operation during the multi-bank refresh operation and the unshaded banks in FIG. 4b are masked during the second multi-bank refresh operation. In other words, the unshaded banks do not receive a refresh operation during the second multi-bank refresh operation.

In the embodiment of FIG. 4c, banks 5, 9, and 13 are shown as “already refreshed” meaning that during the same refresh period, banks 5, 9, and 13 received a refresh operation (e.g., 400b of FIG. 4b) and should a subsequent mask operation during the same refresh period identify them as part of subset of memory banks for a multi-bank refresh operation, they will be skipped.

In some embodiments, the number of high bits, or “1”s, included in the mask code may determine the number of banks to have a refresh operation performed at a time. For example, in the embodiment of FIG. 4c, the mask code includes two high bits resulting in four banks being included in the multi-bank refresh operation. Other mask codes may include more or fewer high bits and thus more or fewer banks may be included in the multi-bank refresh operation.

FIG. 4d is a diagram of a multi-bank refresh operation according to some embodiments of the present disclosure. Memory array 410d may be an implementation of memory array 400a of FIG. 4a, 410b of FIG. 4b, 410c of FIG. 4c, and/or memory array 218 of FIG. 2. For example, the memory banks of FIG. 4d may be an implementation of the memory banks BANK0-BANKN of FIG. 2. The memory array 410d is shown with 128 memory banks. More or fewer banks may be included in the memory arrays of other embodiments.

In some embodiments, the multi-bank refresh operation 400d may be an implementation of a third multi-bank refresh operation performed responsive to a third multi-bank refresh command REFmb of FIG. 3 during the refresh period. During the third multi-bank refresh operation 400d, a row, such as a row associated with a row address RXADD of FIG. 2, may be refreshed in a third subset of memory banks at one time. The third subset of memory banks may be identified by a third mask operation performed using a second seed address (e.g., MBR_seed) and a third mask code, which may be included in the third multi-bank refresh command (e.g., REFmb). The seed address (e.g., MBR_seed) may be a bank address. The bank address may be identified as a binary number and/or a hexadecimal number. For example, in the embodiment of FIG. 4d, the second seed address is 0000_0110 which translates to hexadecimal number 0x06. Bank address 0000_0110 may correspond to bank 6 of the memory array 410c (e.g., 400a of FIG. 4a, 410b of FIG. 4b,410c of FIG. 4c, and/or 218 of FIG. 2) when converted from binary to decimal. The mask code may be represented as a series of binary digits, or bits, which may also be represented as a hexadecimal number. For example, in the embodiment of FIG. 4d, the third mask code is 0110_1000 which may be represented as hexadecimal number 0x68.

In an example third mask operation, the third subset of memory banks may be identified by applying the third mask code to the second seed address. For example, each binary digit of the series of binary digits that make up the third mask code may be added individually and in combination to the binary digits of the second seed address. The resulting series of binary digits of each combination then corresponds to a bank address to be included in the third subset of memory banks to have a refresh operation performed on it during the third multi-bank refresh operation. In the embodiment of FIG. 4d, the third mask operation is performed with the second seed address 0000_0110 and the third mask code 0110_1000. The third mask operation identifies a first bank of the third subset of memory banks by changing the high bits, or “1”s, of the mask code to low, or “0” (e.g., 0000_0000) and applying the third mask code to the second seed address to identify bank address 0000_0110 as the first bank address of the third subset of memory banks, or bank 6 when converted from a binary number to a decimal number as indicated in FIG. 4d as bank 6 being shaded.

The third mask operation identifies a second bank of the third subset of memory banks by changing one of the high bits, or “1”s, of the mask code to low, or “0” to create mask code 0000_1000 and applying the third mask code to the second seed address to identify bank address 0000_1110 as the second bank address of the third subset of memory banks. This bank address, when converted from a binary number to a decimal number, identifies bank 14 as indicated in FIG. 4d by bank 14 being shaded.

The third mask operation identifies a third bank of the subset of memory banks by changing a different one of the high bits, or “1”s, of the mask code to low, or “0” to create mask code 0001_0000 and applying the third mask code to the second seed address to identify bank address 0001_0110 as the third bank address of the third subset of memory banks. This bank address identifies, when converted from a binary number to a decimal number, bank 38 as indicated in FIG. 4d by bank 38 being shaded.

The third mask operation continues by changing each bit of the third mask code one at a time and in combination until the third mask operation identifies a final bank of the third subset of memory banks by applying the third mask code without changes, in other words the third mask code as it was provided by the third multi-bank refresh command, to the second seed address (e.g., 0110_1000) to identify bank address 0110_0110 as the final bank address of the third subset of memory banks. This bank address, when converted from a binary number to a decimal number, identifies bank 110 as indicated in FIG. 4d by bank 110 being shaded. Thus, the shaded banks 6, 14, 38, 46, 70, 78, 102, and 110 receive a refresh operation during the third multi-bank refresh operation and the unshaded banks in FIG. 4c are masked during the third multi-bank refresh operation. In other words, the unshaded banks do not receive a refresh operation during the third multi-bank refresh operation. The banks shaded as “already refreshed” received refresh operations during earlier multi-bank refresh operations in the same refresh period (e.g., 400b of FIG. 4b and/or 400c of FIG. 4c).

In some embodiments, the number of high bits, or “1”s, included in the mask code may determine the number of banks to have a refresh operation performed at a time. For example, in the embodiment of FIG. 4d, the mask code includes three high bits resulting in eight banks being included in the multi-bank refresh operation. Other mask codes may include more or fewer high bits and thus more or fewer banks may be included in the multi-bank refresh operation.

FIG. 4e is a diagram of a multi-bank refresh operation according to some embodiments of the present disclosure. Memory array 410e may be an implementation of memory array 400a of FIG. 4a, 410b-d of FIGS. 4b-d, and/or memory array 218 of FIG. 2. For example, the memory banks of FIG. 4e may be an implementation of the memory banks BANK0-BANKN of FIG. 2. The memory array 410e is shown with 128 memory banks. More or fewer banks may be included in the memory arrays of other embodiments.

In some embodiments, the multi-bank refresh operation 400e may be an implementation of a fourth multi-bank refresh operation performed responsive to a fourth multi-bank refresh command REFmb of FIG. 3 in the refresh period. During the fourth multi-bank refresh operation 400e, a row, such as a row associated with a row address RXADD of FIG. 2, may be refreshed in a fourth subset of memory banks at one time. The fourth subset of memory banks may be identified by a fourth mask operation performed using a seed address (e.g., MBR_seed) and a mask code, which may be included in a multi-bank refresh command (e.g., REFmb). The seed address (e.g., MBR_seed) may be a bank address. The bank address may be identified as a binary number and/or a hexadecimal number. For example, in the embodiment of FIG. 4c, the seed address is unchanged and is the second seed address 0110_0000 which translates to hexadecimal number 0x60. The mask code may be represented as a series of binary digits, or bits, which may also be represented as a hexadecimal number. For example, in the embodiment of FIG. 4c, the fourth mask code is 0000_1111 which can be represented as hexadecimal number 0x0f.

In an example fourth mask operation, the fourth subset of memory banks may be identified by applying the mask code to the seed address. For example, each binary digit of the series of binary digits that make up the fourth mask code may be added individually and in combination to the binary digits of the second seed address. The resulting series of binary digits of each combination then corresponds to a bank address to be included in the fourth subset of memory banks to have a refresh operation performed on it during the multi-bank refresh operation. In the embodiment of FIG. 4c, the fourth mask operation is performed with the second seed address 0110_0000 and the fourth mask code 0000_1111. The fourth mask operation identifies a first bank of the fourth subset of memory banks by changing the high bits, or “1”s, of the mask code to low, or “0” (e.g., 0000_0000) and applying the fourth mask code to the second seed address to identify bank address 0110_0000 as the first bank address of the fourth subset of memory banks, or bank 96 when converted from a binary number to a decimal number as indicated as shaded in FIG. 4c.

The fourth mask operation identifies a second bank of the fourth subset of memory banks by changing one of the high bits, or “1”s, of the fourth mask code to low, or “0” to create mask code 0000_0001 and applying the mask code to the second seed address to identify bank address 0110_0001 as the second bank address of the fourth subset of memory banks. This bank address, when converted from a binary number to a decimal number, identifies bank 97 as indicated in FIG. 4e by bank 97 being shaded. Also indicated in FIG. 4e is that bank 97 is to be skipped, for example it is marked with an “X,” because it was included in the second subset of memory banks in a multi-bank refresh operation (e.g., 400c of FIG. 4c) that occurred earlier in the same refresh period.

The mask operation identifies a third bank of the fourth subset of memory banks by changing a different one of the high bits, or “1”s, of the mask code to low, or “0” to create mask code 0000_0010 and applying the mask code to the seed address to identify bank address 0110_0001 as the third bank address of the subset of memory banks. This bank address identifies, when converted from a binary number to a decimal number, bank 98 as indicated in FIG. 4e by bank 98 being shaded.

The fourth mask operation continues until the fourth mask operation identifies a final bank of the fourth subset of memory banks by applying the mask code without changes to the seed address (e.g., 0000_1111) to identify bank address 0110_1111 as the final bank address of the fourth subset of memory banks. This bank address, when converted from a binary number to a decimal number, identifies bank 111 as indicated in FIG. 4e by bank 111 being shaded. Thus, the shaded banks 96-111, with banks 97, 102, and 110 skipped, receive a refresh operation during the fourth multi-bank refresh operation and the unshaded banks in FIG. 4e are masked during the fourth multi-bank refresh operation. In other words, the unshaded banks do not receive a refresh operation during the fourth multi-bank refresh operation.

In the embodiment of FIG. 4e, several banks are shown as “already refreshed” meaning that during the same refresh period, the “already refreshed” banks received a refresh operation and should a subsequent mask operation during the same refresh period identify them as part of subset of memory banks for a multi-bank refresh operation, they are skipped.

In some embodiments, the number of high bits, or “1”s, included in the mask code may determine the number of banks to have a refresh operation performed at a time. For example, in the embodiment of FIG. 4e, the mask code includes four high bits resulting in sixteen banks being included in the multi-bank refresh operation. Other mask codes may include more or fewer high bits and thus more or fewer banks may be included in the multi-bank refresh operation.

FIG. 4f is a diagram of a multi-bank refresh operation according to some embodiments of the present disclosure. Memory array 410f may be an implementation of memory array 400a of FIG. 4a, 410b-e of FIGS. 4b-e, and/or memory array 218 of FIG. 2. For example, the memory banks of FIG. 4f may be an implementation of the memory banks BANK0-BANKN of FIG. 2. The memory array 410f is shown with 128 memory banks. More or fewer banks may be included in the memory arrays of other embodiments.

In some embodiments, the multi-bank refresh operation 400f may be an implementation of a fifth multi-bank refresh operation performed responsive to a fifth multi-bank refresh command REFmb of FIG. 3 in the refresh period. During the fifth multi-bank refresh operation 400f, a row, such as a row associated with a row address RXADD of FIG. 2, may be refreshed in a fifth subset of memory banks at one time. The fifth subset of memory banks may be identified by a fifth mask operation performed using a third seed address (e.g., MBR_seed) and a fifth mask code, which may be included in the fifth multi-bank refresh command (e.g., REFmb). The third seed address (e.g., MBR_seed) may be a bank address. The bank address may be identified as a binary number and/or a hexadecimal number. For example, in the embodiment of FIG. 4f, the third seed address is 0010_0000 which translates to hexadecimal number 0x20. The fifth mask code may be represented as a series of binary digits, or bits, which may also be represented as a hexadecimal number. For example, in the embodiment of FIG. 4f, the fifth mask code is 0001_1111 which can be represented as hexadecimal number 0x1f.

In an example fifth mask operation, the fifth subset of memory banks may be identified by applying the fifth mask code to the third seed address. For example, each binary digit of the series of binary digits that make up the mask code may be added individually and in combination to the binary digits of the seed address. The resulting series of binary digits of each combination then corresponds to a bank address to be included in the fifth subset of memory banks to have a refresh operation performed on it during the fifth multi-bank refresh operation. In the embodiment of FIG. 4c, the fifth mask operation is performed with the third seed address 0010_0000 and the fifth mask code 0001_1111. The fifth mask operation identifies a first bank of the fifth subset of memory banks by changing the high bits, or “1”s, of the mask code to low, or “0” (e.g., 0000_0000) and applying the mask code to the seed address to identify bank address 0010_0000 as the first bank address of the fifth subset of memory banks, or bank 32 when converted from a binary number to a decimal number as indicated as shaded in FIG. 4f.

As discussed herein, the fifth mask operation continues until the fifth mask operation identifies a final bank of the fifth subset of memory banks by applying the fifth mask code without changes to the third seed address (e.g., 0010_0000) to identify bank address 0011_1111 as the final bank address of the fifth subset of memory banks. This bank address, when converted from a binary number to a decimal number, identifies bank 63 as indicated in FIG. 4f by bank 63 being shaded. Thus, the shaded banks 32-63, with banks 33, 38, and 46 skipped, receive a refresh operation during the fifth multi-bank refresh operation and the unshaded banks in FIG. 4f are masked during the fifth multi-bank refresh operation. In other words, the unshaded banks do not receive a refresh operation during the fifth multi-bank refresh operation.

In the embodiment of FIG. 4e, several banks are shown as “already refreshed” meaning that during the same refresh period, the “already refreshed” banks received a refresh operation and should a subsequent mask operation during the same refresh period identify them as part of subset of memory banks for a multi-bank refresh operation, they are skipped.

In some embodiments, the number of high bits, or “1”s, included in the mask code may determine the number of banks to have a refresh operation performed at a time. For example, in the embodiment of FIG. 4f, the mask code includes 5 high bits resulting in thirty-two banks being included in the multi-bank refresh operation. Other mask codes may include more or fewer high bits and thus more or fewer banks may be included in the multi-bank refresh operation.

FIG. 4g is a diagram of a multi-bank refresh operation according to some embodiments of the present disclosure. Memory array 410g may be an implementation of memory array 400a of FIG. 4a, 410b-f of FIGS. 4b-f, and/or memory array 218 of FIG. 2. For example, the memory banks of FIG. 4g may be an implementation of the memory banks BANK0-BANKN of FIG. 2. The memory array 410g is shown with 128 memory banks. More or fewer banks may be included in the memory arrays of other embodiments.

In some embodiments, the multi-bank refresh operation 400g may be an implementation of a sixth multi-bank refresh operation performed responsive to a sixth multi-bank refresh command REFmb of FIG. 3 during the refresh period. During the sixth multi-bank refresh operation 400g, a row, such as a row associated with a row address RXADD of FIG. 2, may be refreshed in a sixth subset of memory banks at one time. The sixth subset of memory banks may be identified by a sixth mask operation performed using a fourth seed address (e.g., MBR_seed) and a sixth mask code, which may be included in the sixth multi-bank refresh command (e.g., REFmb). The fourth seed address (e.g., MBR_seed) may be a bank address. The bank address may be identified as a binary number and/or a hexadecimal number. For example, in the embodiment of FIG. 4g, the fourth seed address is 0000_0000 which translates to hexadecimal number 0x00. The sixth mask code may be represented as a series of binary digits, or bits, which may also be represented as a hexadecimal number. For example, in the embodiment of FIG. 4g, the sixth mask code is 0111_1111 which can be represented as hexadecimal number 0x7f.

In an example mask operation, the sixth subset of memory banks may be identified by applying the sixth mask code to the fourth seed address. For example, each binary digit of the series of binary digits that make up the mask code may be added individually and in combination to the binary digits of the seed address. The resulting series of binary digits of each combination then corresponds to a bank address to be included in the sixth subset of memory banks to have a refresh operation performed on it during the sixth multi-bank refresh operation. In the embodiment of FIG. 4g, the sixth mask operation is performed with the fourth seed address 0000_0000 and the sixth mask code 0111_1111. The sixth mask operation identifies a first bank of the sixth subset of memory banks by changing the high bits, or “1”s, of the mask code to low, or “0” (e.g., 0000_0000) and applying the mask code to the seed address to identify bank address 0000_0000 as the first bank address of the subset of memory banks, or bank 0 when converted from a binary number to a decimal number as indicated as shaded in FIG. 4g.

As discussed herein, the sixth mask operation continues until the sixth mask operation identifies a final bank of the sixth subset of memory banks by applying the mask code without changes to the seed address (e.g., 0000_0000) to identify bank address 0111_1111 as the final bank address of the sixth subset of memory banks. This bank address, when converted from a binary number to a decimal number, identifies bank 127 as indicated in FIG. 4g by bank 127 being shaded. Thus, the shaded banks 0-127, with some banks skipped, receive a refresh operation during the sixth multi-bank refresh operation and the unshaded banks in FIG. 4g are masked during the sixth multi-bank refresh operation. In other words, the unshaded banks do not receive a refresh operation during the sixth multi-bank refresh operation. The multi-bank refresh operation 400g may in practice be the same as an all bank refresh operation that performs a refresh operation on a row (e.g., RXADD) from every memory bank of the memory array 410g (e.g., 218 of FIG. 2, 400a of FIG. 4a, and/or 410b-f of FIGS. 4b-f).

In some embodiments, the number of high bits, or “1”s, included in the mask code may determine the number of banks to have a refresh operation performed at a time. For example, in the embodiment of FIG. 4g, the mask code includes seven high bits resulting in 128 banks being included in the multi-bank refresh operation. Other mask codes may include more or fewer high bits and thus more or fewer banks may be included in the multi-bank refresh operation.

FIG. 4h is a diagram of a multi-bank refresh operation according to some embodiments of the present disclosure. Memory array 410h may be an implementation of memory array 400a of FIG. 4a, 410b-g of FIGS. 4b-g, and/or memory array 218 of FIG. 2. For example, the memory banks of FIG. 4h may be an implementation of the memory banks BANK0-BANKN of FIG. 2. The memory array 410h is shown with 128 memory banks. More or fewer banks may be included in the memory arrays of other embodiments.

In some embodiments, the multi-bank refresh operation 400h may be an implementation of a first multi-bank refresh operation performed responsive to a first multi-bank refresh command REFmb of FIG. 3 in a second refresh period. During multi-bank refresh operation 400h, a row, such as a row associated with a row address RXADD of FIG. 2, may be refreshed in a subset of memory banks at one time. The subset of memory banks may be identified by a mask operation performed using a seed address (e.g., MBR_seed) and a mask code, which may be included in a multi-bank refresh command (e.g., REFmb). The seed address (e.g., MBR_seed) may be a bank address. The bank address may be identified as a binary number and/or a hexadecimal number. For example, in the embodiment of FIG. 4h, the seed address is 0100_0000 which translates to hexadecimal number 0x40. The mask code may be represented as a series of binary digits, or bits, which may also be represented as a hexadecimal number. For example, in the embodiment of FIG. 4f, the mask code is 0001_1111 which can be represented as hexadecimal number 0x1f.

In an example mask operation, the subset of memory banks may be identified by applying the mask code to the seed address. For example, each binary digit of the series of binary digits that make up the mask code may be added individually and in combination to the binary digits of the seed address. The resulting series of binary digits of each combination then corresponds to a bank address to be included in the subset of memory banks to have a refresh operation performed on it during the multi-bank refresh operation. In the embodiment of FIG. 4h, the mask operation is performed with seed address 0100_0000 and mask code 0001_1111. The mask operation identifies a first bank of the subset of memory banks by changing the high bits, or “1”s, of the mask code to low, or “0” (e.g., 0000_0000) and applying the mask code to the seed address to identify bank address 0100_0000 as the first bank address of the subset of memory banks, or bank 64 when converted from a binary number to a decimal number as indicated as shaded in FIG. 4h.

As discussed herein, the mask operation continues until the mask operation identifies a final bank of the subset of memory banks by applying the mask code without changes to the seed address (e.g., 0100_0000) to identify bank address 0101_1111 as the final bank address of the subset of memory banks. This bank address, when converted from a binary number to a decimal number, identifies bank 95 as indicated in FIG. 4f by bank 95 being shaded. Thus, the shaded banks 64-95, with no banks skipped, receive a refresh operation during the multi-bank refresh operation and the unshaded banks in FIG. 4h are masked during the multi-bank refresh operation. In other words, the unshaded banks do not receive a refresh operation during the multi-bank refresh operation. No banks are skipped or marked as “already refreshed” because this is the first multi-bank refresh operation in the second refresh period. In other words, the maximum amount of time that can pass between refresh operations to prevent information loss has passed and all banks may receive a refresh operation.

In some embodiments, the number of high bits, or “1”s, included in the mask code may determine the number of banks to have a refresh operation performed at a time. For example, in the embodiment of FIG. 4h, the mask code includes five high bits resulting in thirty-two banks being included in the multi-bank refresh operation. Other mask codes may include more or fewer high bits and thus more or fewer banks may be included in the multi-bank refresh operation.

The multi-bank refresh operations of FIGS. 4b-4h is an example sequence of multi-bank refresh operations and is not intended to be limiting. Other embodiments may change the seed address and/or the mask code in different ways and with different frequency. For example, in some embodiments, the seed address may remain unchanged for multiple multi-bank refresh operation and the mask code may change for every multi-bank refresh operation in a sequency. In yet other embodiments, the seed address may change for every multi-bank refresh operation in a sequence and the mask code may change less frequently.

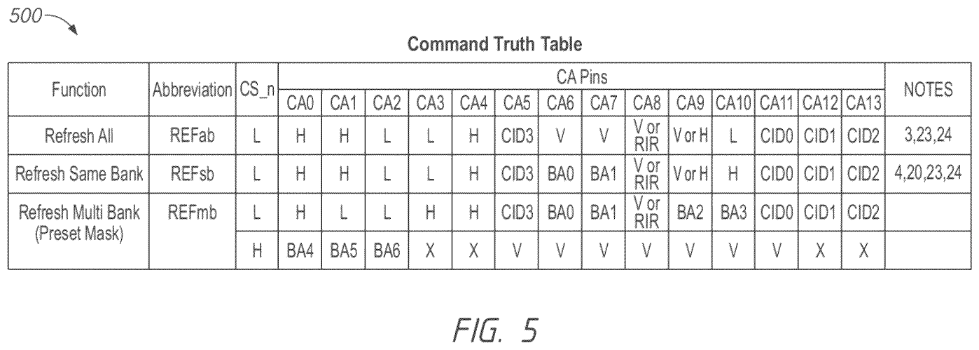

FIG. 5 is a command table representing the commands for refresh operations according to some embodiments of the present disclosure. For example, table 500 may represent external commands issued to a semiconductor device, such as semiconductor device 200, to perform refresh operations.

In some embodiments, each command represented by table 500 may represent a different refresh operation (e.g., REFab, REFsb, REFmb). For example, responsive to a REFab command, an all bank refresh operation is performed; responsive to a REFsb command, a same bank refresh operation is performed; and responsive to a REFmb command, a multi-bank refresh operation is performed. In some embodiments, the multi-bank refresh command may not include a mask code because the mask code is preset, such as by a user. The preset mask code may be stored in a mode register (e.g., 230 of FIG. 2) in some embodiments.

In the table 500 of FIG. 5, “L” indicates a low logic state and “H” indicates a high logic state for the corresponding command terminal CA, “CIDn” indicates an nth bit of chip identification information, “BAm” indicates an mth bit of a bank address, “V” indicates a valid logic state, and “RIR” indicates a refresh interval rate.

In some embodiments, the commands represented by table 500 may be transmitted by a controller (e.g., 102 of FIG. 1). The command may be read by command/address input circuit (e.g., 202 of FIG. 2) and the command/address input circuit (e.g., 202 of FIG. 2) may transfer the bank address (e.g., BAm bits) to the address decoder (e.g., 204 of FIG. 2) and the command signals and the mask code (e.g., mBAp bits) to the command decoder (e.g., 206 of FIG. 2). The address decoder (e.g., 204 of FIG. 2) may supply a decoded seed address (e.g., MBR_seed) to a refresh control circuit (e.g., 216 of FIG. 2) based on the bank address (e.g., BAm bits), which may indicate the bank of the memory array (e.g., 218 of FIG. 2) to use for a multi-bank refresh operation. The command decoder (e.g., 206 of FIG. 2) may supply a decoded multi-bank refresh command (e.g., REFmb) to the refresh control circuit (e.g., 216 of FIG. 2).

Responsive to receiving the multi-bank refresh command (e.g., REFmb) and the seed address (e.g., MBR_seed), the refresh control circuit (e.g., 216 of FIG. 2) may perform a multi-bank refresh operation on a subset of memory banks from the memory array (e.g., 218 of FIG. 2). The subset of memory banks may be identified by the refresh control circuit (e.g., 216 of FIG. 2) based on the seed address (e.g., MBR_seed) and the mask code (e.g., MBR_mask). Responsive to the multi-bank refresh command, the refresh control circuit (e.g., 216 of FIG. 2) may receive the mask code. The mask code may be preset, such as by a user. In some embodiments, the mask code may be stored in a mode register (e.g., 230 of FIG. 2) and responsive to the multi-bank refresh command (e.g., REFmb), the refresh control circuit (e.g., 216 of FIG. 2) may perform a mode register read operation to receive the mask code stored in the mode register (e.g., 230 of FIG. 2).

The refresh control circuit (e.g., 216 of FIG. 2) may perform a mask operation to identify the subset of memory banks. The mask code may include a number, or a sequence, of binary digits and the mask operation may include apply the binary digits to the seed address (e.g., MBR_seed) such that the multi-bank refresh operation will include performing a refresh operation on a subset of memory banks and mask the remaining memory banks, as in the refresh control circuit (e.g., 216 of FIG. 2) will not perform a refresh operation on the masked memory banks. The multi-bank refresh operation may include refreshing a word line corresponding to a refresh row address (e.g., RXADD) identified by the refresh control circuit (e.g., 216 of FIG. 2) in each of the memory banks of the subset of memory banks identified by the mask operation.

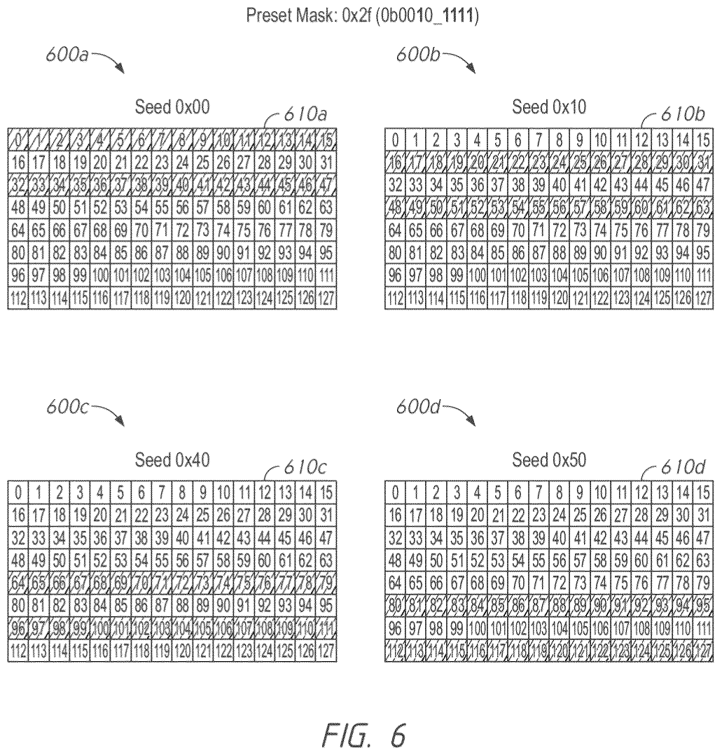

FIG. 6 is a diagram of multi-bank refresh operations with a preset mask code according to some embodiments of the present disclosure. Memory arrays 610a-d may be an implementation of memory array 400a of FIG. 4a, 410b-h of FIGS. 4b-h, and/or memory array 218 of FIG. 2. For example, the memory banks of FIG. 6 may be an implementation of the memory banks BANK0-BANKN of FIG. 2. The memory arrays 610a-d are shown with 128 memory banks. More or fewer banks may be included in the memory arrays of other embodiments.

In some embodiments, the multi-bank refresh operations 600a-d may be implementations of a multi-bank refresh operation performed responsive to the multi-bank refresh command REFmb of FIG. 5. In some embodiments, the multi-bank refresh operations 600a-d may occur in a refresh period. In the sequence of multi-bank refresh operations of FIG. 6, the seed addresses and mask codes used in the multi-bank refresh operations 600a-d are examples. In other embodiments, other seed addresses and mask codes may be used.

During multi-bank refresh operations 600a-d, a row, such as a row associated with a row address RXADD of FIG. 2, may be refreshed in a subset of memory banks at one time. The subset of memory banks may be identified by a mask operation performed using a seed address (e.g., MBR_seed) and a mask code. The mask code may be preset, such as by a user. In some embodiments, the mask code may be stored for use by the memory device (e.g., 106(0)-(p) of FIG. 1 and/or 200 of FIG. 2). For example, the mask code may be stored in a mode register (e.g., 230 of FIG. 2). In the embodiment of FIG. 6, the mask code is 0010_1111 (i.e., 0x2f in hexadecimal) and is the same for each multi-bank refresh operation. This mask code results in the masking of 96 of the 128 banks and thus a subset of 32 memory banks will be included in each multi-bank refresh operation. In this way, all banks of the memory array of 128 banks may be refreshed with four multi-bank refresh commands by changing the seed address. In other embodiments, the mask code may be set to mask more or fewer memory banks and thus require fewer or more multi-bank refresh commands to refresh the entire memory array.

The seed address (e.g., MBR_seed) may be a bank address. The bank address may be identified as a binary number and/or a hexadecimal number as described herein. For example, the multi-bank refresh operation 600a has a seed address of 0000_0000 which translates to hexadecimal number 0x00. The mask operation of multi-bank refresh operation 600a applies the preset mask code 0010_1111 to the seed address 0000_0000 to identify memory banks 0-15 and 32-47, shown as shaded in memory array 600a, as the subset of memory banks for the multi-bank refresh operation.

The multi-bank refresh operation 600b has a seed address of 0001_0000 which translates to hexadecimal number 0x10. The mask operation of multi-bank refresh operation 600b applies the preset mask code 0010_1111 to the seed address 0001_0000 to identify as described herein memory banks 16-31 and 48-63, shown as shaded in memory array 600b, as the subset of memory banks for the multi-bank refresh operation.

The multi-bank refresh operation 600c has a seed address of 0100_0000 which translates to hexadecimal number 0x40. The mask operation of multi-bank refresh operation 600c applies the preset mask code 0010_1111 to the seed address 0100_0000 to identify as described herein memory banks 64-79 and 96-111, shown as shaded in memory array 600c, as the subset of memory banks for the multi-bank refresh operation.

The multi-bank refresh operation 600d has a seed address of 0101_0000 which translates to hexadecimal number 0x50. The mask operation of multi-bank refresh operation 600d applies the preset mask code 0010_1111 to the seed address 0101_0000 to identify as described herein memory banks 80-96 and 112-127, shown as shaded in memory array 600d, as the subset of memory banks for the multi-bank refresh operation.

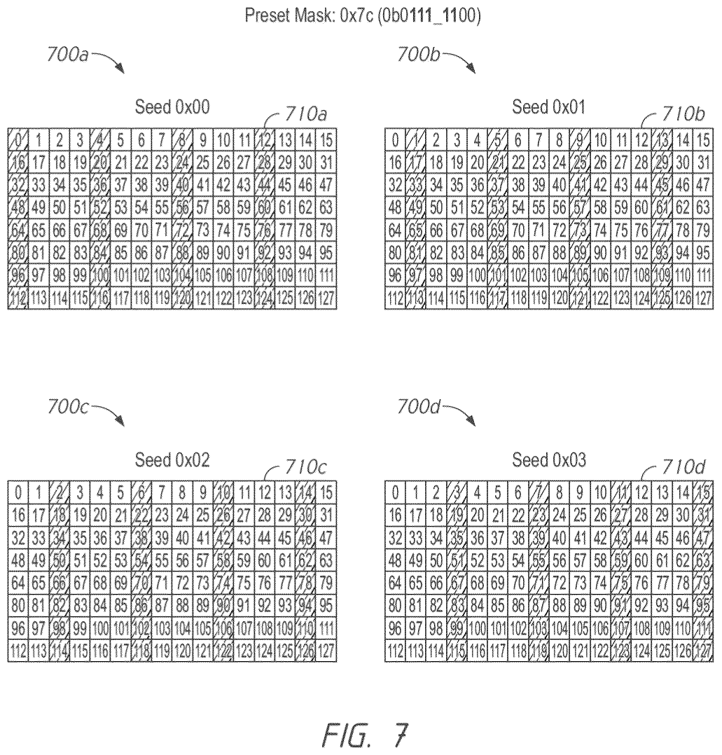

FIG. 7 is a diagram of multi-bank refresh operations with a preset mask code according to some embodiments of the present disclosure. Memory arrays 710a-d may be an implementation of memory arrays 610a-d of FIG. 6, 400a of FIG. 4a, 410b-h of FIGS. 4b-h, and/or memory array 218 of FIG. 2. For example, the memory banks of FIG. 7 may be an implementation of the memory banks BANK0-BANKN of FIG. 2. The memory arrays 710a-d are shown with 128 memory banks. More or fewer banks may be included in the memory arrays of other embodiments.

In some embodiments, the multi-bank refresh operations 700a-d may be implementations of a multi-bank refresh operation performed responsive to the multi-bank refresh command REFmb of FIG. 5. In some embodiments, the multi-bank refresh operations 700a-d may occur in a refresh period. In the sequence of multi-bank refresh operations of FIG. 7, the seed addresses and mask codes used in the multi-bank refresh operations 700a-d are examples. In other embodiments, other seed addresses and mask codes may be used.

During multi-bank refresh operations 700a-d, a row, such as a row associated with a row address RXADD of FIG. 2, may be refreshed in a subset of memory banks at one time. The subset of memory banks may be identified by a mask operation performed using a seed address (e.g., MBR_seed) and a mask code. The mask code may be preset, such as by a user. In some embodiments, the mask code may be stored for use by the memory device (e.g., 106(0)-(p) of FIG. 1 and/or 200 of FIG. 2). For example, the mask code may be stored in a mode register (e.g., 230 of FIG. 2). In the embodiment of FIG. 7, the mask code is 0111_1100 (i.e., 0x7c in hexadecimal) and is the same for each multi-bank refresh operation. This mask code results in the masking of 96 of the 128 banks and thus a subset of 32 memory banks will be included in each multi-bank refresh operation. In this way, all banks of the memory array of 128 banks may be refreshed with four multi-bank refresh commands by changing the seed address. In other embodiments, the mask code may be set to mask more or fewer memory banks and thus require fewer or more multi-bank refresh commands to refresh the entire memory array.

The seed address (e.g., MBR_seed) may be a bank address. The bank address may be identified as a binary number and/or a hexadecimal number as described herein. For example, the multi-bank refresh operation 700a has a seed address of 0000_0000 which translates to hexadecimal number 0x00. The mask operation of multi-bank refresh operation 700a applies the preset mask code 0111_1100 to the seed address 0000_0000 to identify as described herein the 32 shaded memory banks of memory array 710a as the subset of memory banks for the multi-bank refresh operation.

The multi-bank refresh operation 700b has a seed address of 0000_0001 which translates to hexadecimal number 0x01. The mask operation of multi-bank refresh operation 700b applies the preset mask code 0111_1100 to the seed address 0000_0001 to identify as described herein the 32 shaded memory banks of memory array 710b as the subset of memory banks for the multi-bank refresh operation.

The multi-bank refresh operation 700c has a seed address of 0000_0010 which translates to hexadecimal number 0x02. The mask operation of multi-bank refresh operation 700c applies the preset mask code 0111_1100 to the seed address 0000_0010 to identify the 32 shaded memory banks of memory array 710c as the subset of memory banks for the multi-bank refresh operation.

The multi-bank refresh operation 700d has a seed address of 0000_0011 which translates to hexadecimal number 0x03. The mask operation of multi-bank refresh operation 700d applies the preset mask code 0111_1100 to the seed address 0000_0011 to identify as described herein the 32 shaded memory banks of memory array 710d as the subset of memory banks for the multi-bank refresh operation.

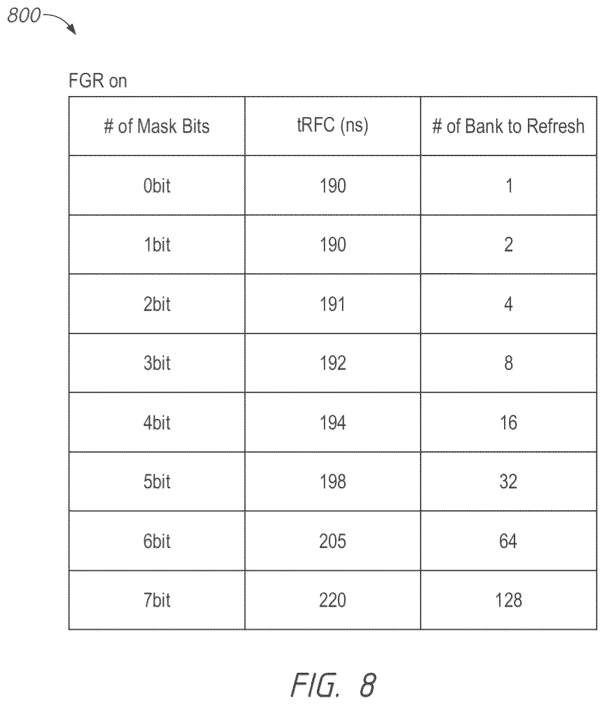

FIG. 8 is a table representing the relative timing of multi-bank refresh

operations according to some embodiments of the present disclosure. Table 800 may represent the time for refresh completion tRFC for multi-bank refresh operations based on the number of banks included in the multi-bank refresh operation as determined by the mask code. The multi-bank refresh operations may be similar to the multi-bank refresh operations 400b-400h of FIGS. 4b-h, 600a-600d of FIG. 6, and/or 700a-700d of FIG. 7.

The time for refresh completion tRFC may be different based on the number of banks included in the multi-bank refresh operation as determined by the mask code. In some embodiments, the time for refresh completion tRFC may become longer as the number of banks included in the multi-bank refresh operation gets larger. For example, the time for refresh completion tRFC for a multi-bank refresh operation where the mask operation identifies a small number of banks, such as one bank, may be shorter than the time for refresh completion tRFC for a multi-bank refresh operation where the mask operation identifies a large number of banks, such as 32 banks. According to some embodiments herein, the number of high bits in a mask code, in other words the number of bits set to “1” in the mask code, may determine the number of memory banks included in a multi-bank refresh operation. For example, a mask code of all low bits, or all “0”s or no high bits, will result in a multi-bank refresh operation on one bank and a mask code with seven high bits will result in a multi-bank refresh operation on 128 banks. The refresh completion time tRFC for a multi-bank refresh operation on one bank may, in some embodiments, take 190 ns whereas the refresh completion time tRFC for a multi-bank refresh operation on 128 banks may take 220 ns.

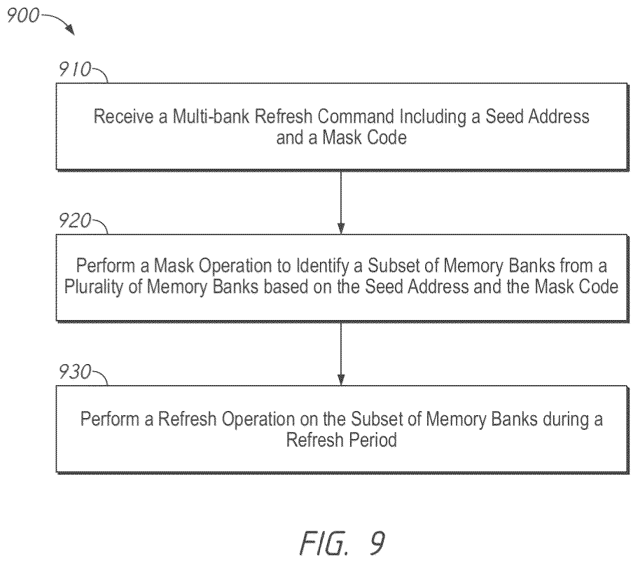

FIG. 9 is a flow chart of a method of performing a multi-bank refresh operation according to some embodiments of the present disclosure. The method 900 may, in some embodiments, be implemented by one or more of the systems or apparatuses described herein. For example, the method may be performed by the semiconductor devices 106(0)-106(p) of FIG. 1 and/or the semiconductor device 200 of FIG. 2.

At block 910, the method 900 may include receiving a refresh command including a seed address and a mask code. The refresh command may be a multi-bank refresh command issued by a memory controller (e.g., 102 of FIG. 1) to a semiconductor device (e.g., 106(0)-106(p) of FIG. 1 and/or 200 of FIG. 2) to perform a refresh operation. For example, the refresh command may be an implementation of a multi-bank refresh command such as REFmb of table 300 of FIG. 3.

At block 920, the method 900 may include performing a mask operation to identify a subset of memory banks from a plurality of memory banks based on the seed address and the mask code. In some embodiments, the plurality of memory banks may be an implementation of memory banks Bank0-BankN of FIG. 1 and/or 400a of FIG. 4a.

At block 930, the method 900 may include performing a refresh operation on the subset of memory banks during a refresh period. The refresh operation may be a multi-bank refresh operation, for example the multi-bank refresh operation 400b of FIG. 4b.

In some embodiments, the method 900 may include receiving a second multi-bank refresh command including a second mask code. The second multi-bank refresh command may be an external command issued by the memory controller (e.g., 102 of FIG. 2) to the semiconductor device (e.g., 106(0)-106(p) of FIG. 1 and/or 200 of FIG. 2) to perform a refresh operation. For example, the second multi-bank command may be an implementation of a multi-bank refresh command such as REFmb of table 300 of FIG. 3.

Responsive to the second multi-bank refresh command, the method 900 may include performing a second mask operation to identify a second subset of memory banks from the plurality of memory banks based on the seed address and the second mask code and performing a second refresh operation on the second subset of memory banks during the refresh period. In some embodiments, the plurality of memory banks may be an implementation of memory banks Bank0-BankN of FIG. 1 and/or 400a of FIG. 4a and the second multi-bank refresh operation may be a multi-bank refresh operation such as 400c of FIG. 4c.

In some embodiments, the method 900 may further include skipping a memory bank of the second subset of memory banks if the memory bank was included in the first subset of memory banks during the refresh operation. For example, the skipped memory bank may be an implementation of memory bank 1 in memory array 410c of FIG. 4c.

In some embodiments, the method 900 may further include the subset of memory banks including all of the memory banks of the plurality of memory banks based on the mask code. For example, the mask code may be an implementation of the mask code of multi-bank refresh operation 400g of FIG. 4g.

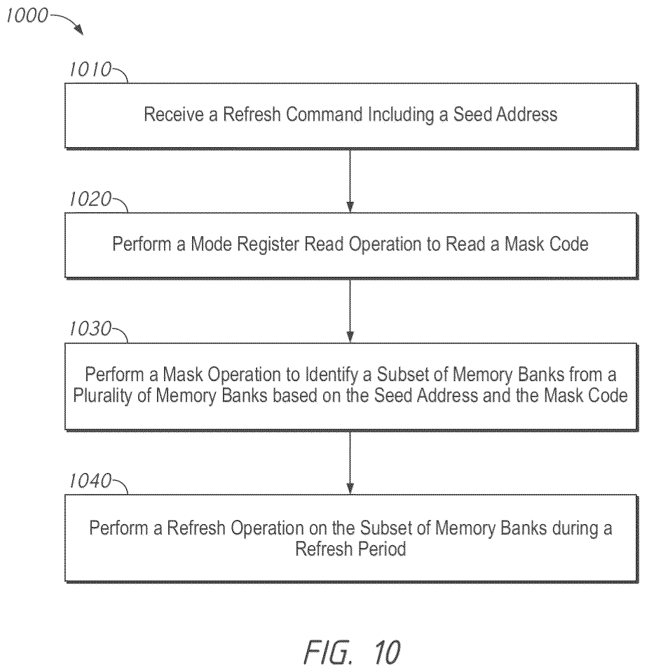

FIG. 10 is a flow chart of a method of performing a multi-bank refresh operation with a preset mask code according to some embodiments of the present disclosure. The method 1000 may, in some embodiments, be implemented by one or more of the systems or apparatuses described herein. For example, the method may be performed by the semiconductor devices 106(0)-106(p) of FIG. 1 and/or the semiconductor device 200 of FIG. 2.

At block 1010, the method 1000 may include receiving a refresh command including a seed address. The refresh command may be a multi-bank refresh command issued by a memory controller (e.g., 102 of FIG. 1) to a semiconductor device (e.g., 106(0)-106(p) of FIG. 1 and/or 200 of FIG. 2) to perform a refresh operation. For example, the refresh command may be an implementation of a multi-bank refresh command such as REFmb of table 500 of FIG. 5.

At block 1020, the method 1000 may include performing a mode register read operation to read a mask code. In some embodiments the mode register may be an implementation of mode register 230 of FIG. 2.

At block 1030, the method 1000 may include performing a mask operation to identify a subset of memory banks from a plurality of memory banks based on the seed address and the mask code. In some embodiments, the plurality of memory banks may be an implementation of memory banks Bank0-BankN of FIG. 1 and/or 400a of FIG. 4a.

At block 1040, the method 1000 may include performing a refresh operation on the subset of memory banks during a refresh period. The refresh operation may be a multi-bank refresh operation, for example the multi-bank refresh operation 600a of FIG. 6 and/or 700a of FIG. 7.

In some embodiments, the method 1000 may include receiving a second multi-bank refresh command including a second seed address. The second multi-bank refresh command may be an external command issued by the memory controller (e.g., 102 of FIG. 2) to the semiconductor device (e.g., 106(0)-106(p) of FIG. 1 and/or 200 of FIG. 2) to perform a refresh operation. For example, the second multi-bank command may be a multi-bank refresh command such as REFmb of table 500 of FIG. 5.

Responsive to the second multi-bank refresh command, the method 1000 may include performing a second mask operation to identify a second subset of memory banks from the plurality of memory banks based on the second seed address and the mask code and performing a second refresh operation on the second subset of memory banks during the refresh period. In some embodiments, the plurality of memory banks may be an implementation of memory banks Bank0-BankN of FIG. 1 and/or 400a of FIG. 4a and the second refresh operation may be a multi-bank refresh operation such as multi-bank refresh operation 600b of FIG. 6 and/or 700b of FIG. 7.

In some embodiments, the method 1000 may further include the subset of memory banks including all of the memory banks of the plurality of memory banks based on the mask code. For example, the mask code may be an implementation of the mask code of multi-bank refresh operation 400g of FIG. 4g.

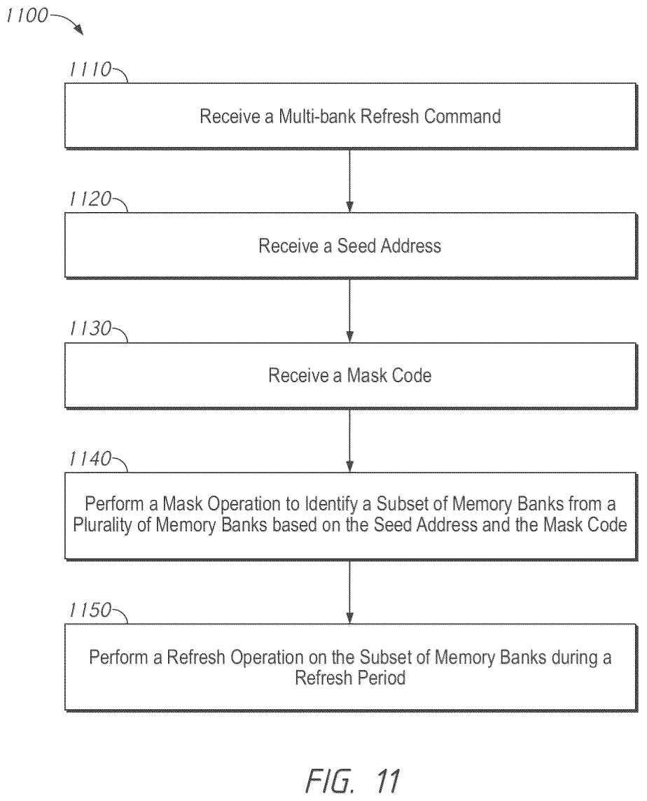

FIG. 11 is a flow chart of a method of performing a multi-bank refresh operation according to some embodiments of the present disclosure. The method 1100 may, in some embodiments, be implemented by one or more of the systems or apparatuses described herein. For example, the method may be performed by the semiconductor devices 106(0)-106(p) of FIG. 1 and/or the semiconductor device 200 of FIG. 2.

At block 1110, the method 1100 may include receiving a multi-bank refresh command. The multi-bank refresh command may be a multi-bank refresh command issued by a memory controller (e.g., 102 of FIG. 1) to a semiconductor device (e.g., 106(0)-106(p) of FIG. 1 and/or 200 of FIG. 2) to perform a refresh operation. For example, the refresh command may be an implementation of a multi-bank refresh command such as REFmb of table 300 of FIG. 3 and/or 500 of FIG. 5.

At block 1120, the method 1100 may include receiving a seed address. In some embodiments the seed address may be part of the multi-bank refresh command such as REFmb of table 300 of FIG. 3 and/or 500 of FIG. 5.

At block 1130, the method 1100 may include receiving a mask code. In some embodiments the mask code may be part of the multi-bank refresh command such as REFmb of table 300 of FIG. 3. In some embodiments, the mask code may be preset, such as by a user, and stored in a register. For example, the mask code may be stored in a mode register, such as mode register 230 of FIG. 2.

At block 1140, the method 1100 may include performing a mask operation to identify a subset of memory banks from a plurality of memory banks based on the seed address and the mask code. In some embodiments, the plurality of memory banks may be an implementation of memory banks Bank0-BankN of FIG. 1 and/or 400a of FIG. 4a.

At block 1150, the method 1100 may include performing a refresh operation on the subset of memory banks during a refresh period. The refresh operation may be a multi-bank refresh operation, for example the multi-bank refresh operation 400b of FIG. 4b, 600a of FIG. 6, and/or 700a of FIG. 7.

In some embodiments, the method 1100 may include receiving a second multi-bank refresh command. The second multi-bank refresh command may be an external command issued by the memory controller (e.g., 102 of FIG. 2) to the semiconductor device (e.g., 106(0)-106(p) of FIG. 1 and/or 200 of FIG. 2) to perform a refresh operation. For example, the second multi-bank command may be a multi-bank refresh command such as REFmb of table 300 of FIG. 3 and/or 500 of FIG. 5.

In some embodiments, the method 1100 may further include receiving a second seed address. For example, the second seed address may be part of the multi-bank refresh command such as REFmb of table 300 of FIG. 3 and/or 500 of FIG. 5.

In some embodiments, the method 1100 may further include receiving a second mask code. For example, the second mask code may be part of the multi-bank refresh command such as REFmb of table 300 of FIG. 3. In some embodiments, the second mask code may be set, such as by a user, and stored in a register. For example, the second mask code may be stored in a mode register, such as mode register 230 of FIG. 2.

Responsive to the second multi-bank refresh command, the method 1100 may include performing a second mask operation to identify a second subset of memory banks from the plurality of memory banks based on the second seed address and the second mask code and performing a second refresh operation on the second subset of memory banks during the refresh period. In some embodiments, the plurality of memory banks may be an implementation of memory banks Bank0-BankN of FIG. 1 and/or 400a of FIG. 4a and the second refresh operation may be a multi-bank refresh operation such as multi-bank refresh operation 400c of FIG. 4c, 600b of FIG. 6, and/or 700b of FIG. 7.

In some embodiments, the method 1100 may further include skipping a memory bank of the second subset of memory banks if the memory bank was included in the first subset of memory banks during the multi-bank refresh operation. For example, the skipped memory bank may be an implementation of memory bank 1 in memory array 410c of FIG. 4c.

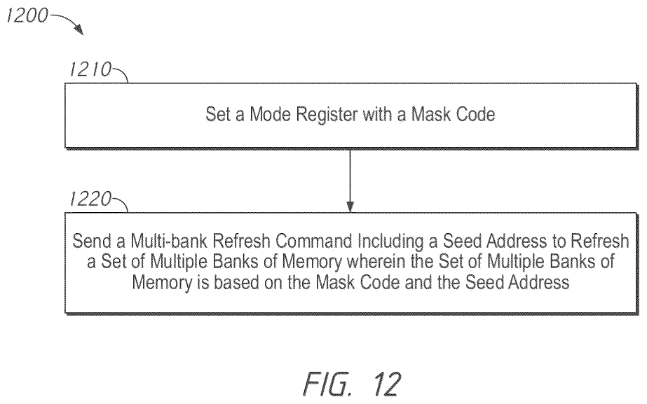

FIG. 12 is a flow chart of a method of performing a multi-bank refresh operation according to some embodiments of the present disclosure. The method 1200 may, in some embodiments, be implemented by one or more of the systems or apparatuses described herein. For example, the method may be performed by the controller 102 of FIG. 1.

At block 1210, the method 1200 may include setting a mode register with a mask code. In some embodiments, the mode register may implement the mode register 230 of FIG. 2. In some embodiments, the mask code may be a sequence of binary digits. In some embodiments, the setting of the mode register with the mask code may be based on a user command.

At block 1220, the method 1200 may include sending a multi-bank refresh command including a seed address to refresh a set of multiple banks of memory and the set of multiple banks of memory is based on the mask code and the seed address. In some embodiments, the multi-bank refresh command may be a command such as REFmb of table 300 of FIG. 3 and/or 500 of FIG. 5. The set of multiple banks to refresh may be a set of banks such as is depicted as shaded in FIG. 6a and/or FIG. 7a.

In some embodiments, the method 1200 may further include sending a second multi-bank refresh command to refresh a second set of multiple banks of memory, the second refresh command including a second seed address. For example, the second multi-bank command may be a multi-bank refresh command such as REFmb of table 500 of FIG. 5. The second set of multiple banks of memory may be a set of banks such as is depicted as shaded in FIG. 6b and/or FIG. 7b.

Example embodiments of the disclosure:
A. A system comprising:
a memory controller configured to provide a multi-bank refresh command to refresh
a first set of multiple banks of memory, the refresh command including a seed address and a mask code; and
a memory device coupled to the memory controller wherein the memory device includes a plurality of memory banks, wherein the memory device is configured to:
receive the multi-bank refresh command; and
perform a refresh operation to refresh the first set multiple banks of the plurality of memory banks based on the seed address and the mask code.
B. The system of paragraph A, wherein the memory controller is further configured to provide a second multi-bank refresh command to refresh a second set of multiple banks of memory, the second multi-bank refresh command including the seed address and a second mask code and wherein the memory device is further configured to:
receive the second refresh command; and
perform a second refresh operation to refresh the second set of multiple banks of memory based on the seed address and the second mask code.
C. The system of paragraph B, wherein the memory device is further configured to skip a memory bank of the second set of multiple banks of memory during the second refresh operation if the memory bank was included in the first set of multiple memory banks.
D. The system of paragraph A, wherein the set of multiple banks includes all memory banks of the plurality of memory banks based on the mask code.
E. The system of paragraph A, wherein the memory device further comprises a refresh control circuit configured to provide a row address associated with a word line and wherein the memory device is further configured to refresh the word line associated with the row address in each bank of the set of multiple memory banks during the refresh operation.
F. A system comprising:
a memory controller configured to provide a multi-bank refresh command to refresh a first set of multiple banks of memory, the multi-bank refresh command including a seed address;
a memory device coupled to the memory controller, wherein the memory device includes a plurality of memory banks and a mode register configured to store a mask code programmed by the memory controller, wherein the memory device is configured to:
receive the multi-bank refresh command from the memory controller;
read the mask code from the mode register; and
perform a refresh operation to refresh the first set multiple banks of the plurality of memory banks based on the seed address and the mask code.
G. The system of paragraph F, wherein the memory controller is further configured to provide a second multi-bank refresh command to refresh a second set of multiple banks of memory, the second refresh command including a second seed address and wherein the memory device is further configured to:
receive the second multi-bank refresh command; and
perform a second refresh operation to refresh the second set of multiple banks of memory based on the second seed address and the mask code.
H. The system of paragraph F, wherein the set of memory banks includes all memory banks of the plurality of memory banks based on the mask code.
I. The system of paragraph F, wherein the mode register is further configured to store the mask code based on a user setting.
J. A method comprising:
receiving a multi-bank refresh command;
receiving a seed address;
receiving a mask code;
performing a mask operation to identify a first subset of memory banks from a plurality of memory banks based on the seed address and the mask code; and
performing a first refresh operation on the first subset of memory banks during a refresh mode.
K. The method of paragraph J, further comprising:
receiving a second multi-bank refresh command
receiving a second mask code;
performing a second mask operation to identify a second subset of memory banks
from the plurality of memory banks based on the seed address and the second mask code; and
performing a second refresh operation on the second subset of memory banks during the refresh mode.
L. The method of paragraph K, further comprising:
skipping a memory bank of the second subset of memory banks during the second refresh operation if the memory bank was included in the first subset of memory banks during the first refresh operation.
M. The method of paragraph J, further comprising:
receiving a second multi-bank refresh command
receiving a second seed address;
performing a second mask operation to identify a second subset of memory banks from the plurality of memory banks based on the second seed address and the mask code; and
performing a second refresh operation on the second subset of memory banks during the refresh mode.
N. The method of paragraph J, wherein the multi-bank refresh command includes the seed address and the mask code.
O. The method of paragraph J, wherein the multi-bank refresh command includes the seed address and wherein the mask code is a setting of a mode register.
P. A method comprising:
setting a mode register, wherein the setting includes a mask code; and
sending a multi-bank refresh command to refresh a set of multiple banks of memory, the refresh command including a seed address, wherein the set of multiple banks of memory is based on the mask code and the seed address.
Q. The method of paragraph P, further comprising sending a second multi-bank refresh command to refresh a second set of multiple banks of memory, the second refresh command including a second seed address.
R. The method of paragraph P, wherein setting the mode register is based on a user command.

It is to be appreciated that any one of the examples, embodiments or processes described herein may be combined with one or more other examples, embodiments and/or processes or be separated and/or performed amongst separate devices or device portions in accordance with the present systems, devices, and methods.

Finally, the discussion herein is intended to be merely illustrative of the present system and should not be construed as limiting the appended claims to any particular embodiment or group of embodiments. Thus, while the present system has been described in particular detail with reference to exemplary embodiments, it should also be appreciated that numerous modifications and alternative embodiments may be devised by those having ordinary skill in the art without departing from the broader and intended spirit and scope of the present system as set forth in the claims that follow. Accordingly, the specification and drawings are to be regarded in an illustrative manner and are not intended to limit the scope of the appended claims.

What is claimed is:

1. An apparatus comprising:
a memory array including a plurality of memory banks; and
a refresh control circuit configured to perform a refresh operation on a first subset of memory banks of the plurality of memory banks in response to a multi-bank refresh command, wherein the first subset of memory banks is based on a seed address and a mask code.

2. The apparatus of claim 1, wherein the refresh control circuit is further configured to perform a mask operation to identify the first subset of memory banks.

3. The apparatus of claim 2, wherein the mask operation comprises adding each digit of the mask code individually and in combination to the seed address.

4. The apparatus of claim 1, wherein the refresh control circuit is further configured to perform the refresh operation on all memory banks of the plurality of memory banks based on the mask code.

5. The apparatus of claim 1, wherein the refresh control circuit is further configured to perform a second refresh operation on a second subset of memory banks of the plurality of memory banks based on a second seed address and a second mask code during a same refresh period as the refresh operation on the first subset of memory banks.

6. The apparatus of claim 1, wherein the seed address and the mask code are included in the multi-bank refresh command.

7. The apparatus of claim 1, wherein the mask code is programmed in a mode register.

8. A method comprising:
receiving a multi-bank refresh command including a seed address and a mask code;
performing a mask operation to identify a subset of memory banks from a plurality of memory banks based on the seed address and the mask code; and
performing a refresh operation on the subset of memory banks.

9. The method of claim 8, further comprising:
receiving a second multi-bank refresh command including a second mask code;
performing a second mask operation to identify a second subset of memory banks from the plurality of memory banks based on the seed address and the second mask code; and
during a same refresh period as the refresh operation on the subset of memory banks, performing a second refresh operation on the second subset of memory banks.

10. The method of claim 9, further comprising:
skipping a memory bank of the second subset of memory banks during the second refresh operation if the memory bank was included in the subset of memory banks during the refresh operation.

11. The method of claim 8, wherein the subset of memory banks includes all of the memory banks of the plurality of memory banks based on the mask code.

12. The method of claim 8, wherein the mask code includes a number of digits based on a number of memory banks in the plurality of memory banks.

13. The method of claim 8, wherein performing the refresh operation further comprises refreshing a word line from each memory bank of the subset of memory banks.

14. The method of claim 8, wherein an amount of time to complete the refresh operation is based on the mask code.

15. The method of claim 8, wherein performing the mask operation comprises adding each digit of the mask code individually and in combination to the seed address.

16. A method comprising:
receiving a multi-bank refresh command including a seed address;
performing a mode register read operation to read a mask code;
performing a mask operation to identify a subset of memory banks from a plurality of memory banks based on the seed address and the mask code; and
performing a first refresh operation on the subset of memory banks during a refresh period.

17. The method of claim 16, further comprising:
receiving a second multi-bank refresh command including a second seed address;
performing a second mask operation to identify a second subset of memory banks from the plurality of memory banks based on the second seed address and the mask code; and
performing a second refresh operation on the second subset of memory banks during the refresh period.

18. The method of claim 16, wherein the subset of memory banks includes all of the memory banks of the plurality of memory banks based on the mask code.

19. The method of claim 16, wherein the mask code is set by a user.

20. The method of claim 16, wherein performing the refresh operation further comprises refreshing a word line from each memory bank of the subset of memory banks.

21. The method of claim 16, wherein an amount of time to complete the refresh operation is based on the mask code.
